(19) United States
(12) Patent Application Publication
(10) Pub. No.: US 2023/0408923 A1
(43) Pub. Date: Dec. 21, 2023

(54) SUBSTRATE LAMINATE, IMAGE SENSOR, AND METHOD FOR MANUFACTURING SUBSTRATE LAMINATE

(71) Applicant: KANEKA CORPORATION, Osaka (JP)

(72) Inventors: Yuta SAITO, Settsu-shi (JP); Ayumu OGAWA, Settsu-shi (JP); Daiki KINOSHITA, Settsu-shi (JP)

(21) Appl. No.: 18/461,427

(22) Filed: Sep. 5, 2023

Related U.S. Application Data
(63) Continuation-in-part of application No. PCT/JP2022/015716, filed on Mar. 29, 2022.

(30) Foreign Application Priority Data
Mar. 29, 2021 (JP) 2021-055638

(51) Int. Cl. G03F 7/075; C09J 163/00; C09J 5/00; B32B 37/12; B32B 17/06; B32B 7/12; B32B 37/24; B32B 38/00; C03C 17/30

(52) U.S. Cl. CPC G03F 7/0757; C03C 2218/328; C09J 5/00; B32B 37/12; B32B 17/06; B32B 7/12; B32B 37/24; B32B 38/0004; C03C 17/30; B32B 2305/74; B32B 2307/54; B32B 2255/26; B32B 2307/542; B32B 2037/243; B32B 2457/00; C09J 163/00

(57) ABSTRACT

A method for manufacturing a substrate laminate includes steps Sa, Sb, Sc, Sd, and Se. In step Sa, a photosensitive composition is applied to one surface of a first substrate to form a coating film on the surface. In step Sb, the coating film is irradiated with an active energy ray through a photomask to form an exposed portion formed of the semi-cured photosensitive composition and a non-exposed portion in the coating film. In step Sc, the non-exposed portion is removed from the first substrate with an alkaline developer to form a patterned coating film on the first substrate. In step Sd, the patterned coating film is heated to obtain a first layer. In step Se, the first layer and a second substrate are bonded to each other with an adhesive interposed therebetween, the adhesive is then cured to obtain a second layer.

### TECHNICAL FIELD

The present invention relates to a substrate laminate, an image sensor, and a method for manufacturing a substrate laminate.

### BACKGROUND ART

Image sensors such as complementary metal-oxide semiconductor (CMOS) sensors and charge-coupled device (CCD) sensors are used in digital cameras, smartphones and the like, and in recent years, the image sensors have been increasingly used and increasingly required to have a smaller size and higher definition along with the popularization of monitoring cameras in automobiles and factories.

A substrate laminate forming the image sensor has, for example, a hollow structure in which a semiconductor element substrate having a light receiving element and a glass substrate are bonded to each other with a patterned layer interposed therebetween. For example, in Japanese Patent Laid-Open Publication No. 2019-62048, a substrate laminate having a hollow structure is obtained by the following procedure.

First, a photosensitive composition is applied to one surface of a first substrate (for example, a glass substrate) to form a coating film on the first substrate. Subsequently, the coating film is irradiated with light through a photomask to form an exposed portion formed of semi-cured photosensitive composition and a non-exposed portion in the coating film. Subsequently, the non-exposed portion is removed from the first substrate with an alkaline developer to form a patterned semi-cured coating film (hereinafter, sometimes referred to as a “pattern film”) on the first substrate. Subsequently, the first substrate on which the pattern film is formed and a second substrate (for example, a semiconductor element substrate) are bonded to each other with the pattern film interposed therebetween, and the pattern film is cured to bond the first substrate and the second substrate. A substrate laminate having a hollow structure is obtained through the process described above.

### SUMMARY OF THE INVENTION

### Problems to be Solved by the Invention

However, foreign matter may adhere to a semi-cured pattern film. If a first substrate and a second substrate are bonded to each other with the pattern film interposed therebetween with foreign matter adhered to the pattern film, a position gap may be generated between the pattern film and the second substrate by the foreign matter. In addition, cracks may be generated in the pattern film by the foreign matter. Therefore, a substrate laminate resistant to ingress of foreign matter is desired.

The technique described in Japanese Patent Laid-Open Publication No. 2019-62048 leaves room for improvement in suppressing ingress of foreign matter while improving adhesiveness between substrates.

The present invention has been made in view of the above-described problems, and an object of the present invention is to provide a substrate laminate which is excellent in adhesiveness between substrates and resistant to ingress of foreign matter, a method for manufacturing the substrate laminate, and an image sensor including the substrate laminate.

### Means for Solving the Problems

A method for manufacturing a substrate laminate according to the present invention is a method for manufacturing a substrate laminate including steps Sa, Sb, Sc, Sd, and Se. In step Sa, a photosensitive composition is applied to one surface of a first substrate to form a coating film on the surface. In step Sb, the coating film is irradiated with an active energy ray through a photomask to form an exposed portion formed of a semi-cured photosensitive composition and a non-exposed portion in the coating film. In step Sc, the non-exposed portion is removed from the first substrate with an alkaline developer to form a patterned coating film on the first substrate. In step Sd, the patterned coating film is heated to further cure the semi-cured photosensitive composition, thereby obtaining a first layer including a patterned cured product. In step Se, the first layer and a second substrate are bonded to each other with an adhesive interposed therebetween, the adhesive is then cured to obtain a second layer that bonds the first layer and the second substrate. The photosensitive composition contains a curable compound having a cationically polymerizable group and a photocationic polymerization initiator, and has alkali solubility. The reaction ratio of the curable compound in the first layer before step Se is 90% or more.

In a method for manufacturing a substrate laminate according to an embodiment of the present invention, the method includes a step Sf1 of dicing a laminated product of the first substrate and the first layer to obtain a singulated laminated product after step Sd and before step Se. In step Se, the first layer of the singulated laminated product and the second substrate are bonded to each other with the adhesive interposed therebetween.

In a method for manufacturing a substrate laminate according to an embodiment of the present invention, the method includes a step Sf2 of dicing a laminated product, in which the first substrate, the first layer, the second layer, and the second substrate are laminated in this order, to obtain a singulated laminated product after step Se.

In a method for manufacturing a substrate laminate according to an embodiment of the present invention, the alkaline developer contains an alkali component, and a content of the alkali component in the first layer before step Se is 1,000 ppm or less.

In a method for manufacturing a substrate laminate according to an embodiment of the present invention, a softening point of the first layer before step Se is 100° C. or higher.

In a method for manufacturing a substrate laminate according to an embodiment of the present invention, an elastic modulus of the first layer before step Se is 1,500 N/mm² or more as measured by a nanoindentation test method at 100° C.

A substrate laminate according to the present invention includes a first substrate, a second substrate, and a cured product layer that bonds the first substrate and the second substrate. The cured product layer includes a first layer formed of a cured product of a photosensitive composition and a second layer formed of a cured product of an adhesive, in this order from the first substrate side. The first layer is patterned.

In a substrate laminate according to an embodiment of the present invention, the photosensitive composition contains a curable compound having a cationically polymerizable group and a photocationic polymerization initiator, and has alkali solubility.

In a substrate laminate according to an embodiment of the present invention, a wall surface of the second layer is a curved surface.

In a substrate laminate according to an embodiment of the present invention, the cured product layer further includes a covering layer covering at least a part of a wall surface of the first layer. The covering layer and the second layer are integrated.

In a substrate laminate according to an embodiment of the present invention, one of the first substrate and the second substrate is a transparent substrate.

In a substrate laminate according to an embodiment of the present invention, one of the first substrate and the second substrate is a transparent substrate, and the other is a semiconductor element substrate.

In a substrate laminate according to an embodiment of the present invention, the cationically polymerizable group is one or more selected from the group consisting of a glycidyl group and an alicyclic epoxy group.

In a substrate laminate according to an embodiment of the present invention, the first substrate is a glass substrate.

In a substrate laminate according to an embodiment of the present invention, the adhesive is an epoxy-based adhesive.

In a substrate laminate according to an embodiment of the present invention, the curable compound is a polysiloxane compound.

In a substrate laminate according to an embodiment of the present invention, the polysiloxane compound further contains one or more alkali-soluble groups selected from the group consisting of a monovalent organic group of the following chemical formula X1, a divalent organic group of the following chemical formula X2, a phenolic hydroxyl group, and a carboxy group.

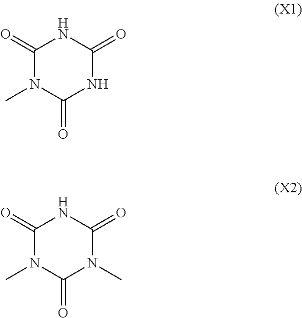

In a substrate laminate according to an embodiment of the present invention, a height of the first layer is 30 μm or more.

In a substrate laminate according to an embodiment of the present invention, the substrate laminate is formed as a hollow structure having a hollow portion between the first substrate and the second substrate.

An image sensor according to the present invention includes the substrate laminate according to the present invention.

### Effects of the Invention

According to the present invention, it is possible to provide a substrate laminate which is excellent in adhesiveness between substrates and resistant to ingress of foreign matter, a method for manufacturing the substrate laminate, and an image sensor including the substrate laminate.

### BRIEF DESCRIPTION OF TIE DRAWINGS

FIG. 1 is a sectional view showing an example of a substrate laminate according to the present invention.

FIG. 2 is a partial sectional view showing another example of a substrate laminate according to the present invention.

FIG. 3 is a partial sectional view showing another example of a substrate laminate according to the present invention.

FIG. 4 is a partial sectional view showing another example of a substrate laminate according to the present invention.

FIG. 5 is a plan view showing a first substrate after formation of a first layer in the manufacture of an example of a substrate laminate according to the present invention.

FIGS. 6A, 6B, and 6C are sectional views showing step by step an example of a method for manufacturing a substrate laminate according to the present invention.

FIGS. 7A, 7B, and 7C are sectional views showing step by step an example of a method for manufacturing a substrate laminate according to the present invention.

FIG. 8 is a plan view showing a first substrate after singulation in the manufacture of an example of a substrate laminate according to the present invention.

### MODE FOR CARRYING OUT THE INVENTION

Preferred embodiments of the present invention will be described in detail below, but the present invention is not limited to these embodiments. The academic documents and patent documents mentioned herein are incorporated herein by reference in their entirety.

First, terms used herein will be described. The term “photopolymerization initiator” refers to a compound that generates an active species (specifically, radical, cation, anion or the like) when irradiated with an active energy ray. The term “photocationic polymerization initiator” refers to a compound that generates a cation (acid) as an active species when irradiated with an active energy ray. The term “photoradical polymerization initiator” refers to a compound that generates a radical as an active species when irradiated with an active energy ray. Examples of the active energy ray include visible light rays, ultraviolet rays, infrared rays, electron beams, X-rays, α-rays, β-rays, and γ-rays.

The term “cationically polymerizable group” refers to a functional group that polymerizes in a chain reaction in the presence of a cation. The term “alkali-soluble group” refers to a functional group that enhances solubility in an alkaline solution by interacting with an alkali or reacting with an alkali. The phrase “a photosensitive composition has alkali-solubility” means that the photosensitive composition contains a compound having an alkali-soluble group. The term “alicyclic epoxy group” refers to a functional group formed by bonding one oxygen atom to two adjacent carbon atoms among carbon atoms forming an alicyclic structure, and examples thereof include a 3,4-epoxycyclohexyl group. The “polysiloxane compound” is a compound having a polysiloxane structure having a siloxane unit (Si—O—Si) as a constituent element. Examples of the polysiloxane structure include chain polysiloxane structures (specifically, linear polysiloxane structures, branched polysiloxane structures and the like) and cyclic polysiloxane structures. The term “epoxy-based adhesive” refers to an adhesive containing a compound having an epoxy group (for example, a compound containing at least two epoxy groups in one molecule) as a main agent. The term “semi-cured state” refers to a state in which the degree of curing can be further increased by a subsequent step (for example, a heating step). The term “solid content” is a nonvolatile component in the composition, and the term “total solid content” means the total amount of composition constituent components excluding solvents.

Unless otherwise specified, the term “main component” of a material means a component contained in the material in the largest amount on a mass basis.

Hereinafter, the name of a compound may be followed by the term “-based” to collectively refer to the compound and derivatives thereof. The term “-based” following the name of a compound to express the name of a polymer means that repeating units of the polymer are derived from the compound or a derivative thereof. Acryl and methacryl may be collectively referred to as “(meth)acryl.” Acrylate and methacrylate may be collectively referred to as “(meth)acrylate.”

Unless otherwise specified, one of the components, functional groups, and the like shown in the present description may be used alone, or two or more thereof may be used in combination.

In the drawings that are referred to in the following description, mainly relevant components are schematically shown for easy understanding, and the size, the number, the shape, and the like of each illustrated component may be different from the actual counterparts for convenience of preparing the drawings. For convenience of description, there may be cases where in the drawings that are described later, the same component parts as those in the drawings described previously are given the same symbols, and descriptions thereof are omitted.

### First Embodiment: Method for Manufacturing Substrate Laminate

A method for manufacturing a substrate laminate according to a first embodiment of the present invention includes steps Sa, Sb, Sc, Sd, and Se. In step Sa, a photosensitive composition is applied to one surface of a first substrate to form a coating film on the surface. In step Sb, the coating film is irradiated with an active energy ray through a photomask to form an exposed portion formed of the semi-cured photosensitive composition and a non-exposed portion in the coating film. In step Sc, the non-exposed portion is removed from the first substrate with an alkaline developer to form a patterned coating film on the first substrate. In step Sd, the patterned coating film is heated to further cure the semi-cured photosensitive composition, thereby obtaining a first layer including a patterned cured product. In step Se, the first layer and a second substrate are bonded to each other with an adhesive interposed therebetween, the adhesive is then cured to obtain a second layer that bonds the first layer and the second substrate. The photosensitive composition contains a curable compound having a cationically polymerizable group and a photocationic polymerization initiator, and has alkali solubility. The reaction ratio of the curable compound in the first layer before step Se is 90% or more.

The reaction ratio of the curable compound in the first layer before step Se is sometimes referred to simply as a “reaction ratio.” The method for measuring the reaction ratio is identical or similar to that in examples described later.

The method for manufacturing a substrate laminate according to the first embodiment enables suppressing ingress of foreign matter into the substrate laminate while enhancing adhesiveness between the substrates. The reason for this is presumed as follows.

In step Sd of the method for manufacturing a substrate laminate according to the first embodiment, the patterned coating film is heated to further cure the semi-cured photosensitive composition, thereby obtaining a first layer including a patterned cured product. Since the reaction ratio of the first layer before step Se is 90% or more, the tackiness of the first layer is lower than that of, for example, the semi-cured pattern film described in Japanese Patent Laid-Open Publication No. 2019-62048, and foreign matter relatively hardly sticks to the layer. In the method for manufacturing a substrate laminate according to the first embodiment, the first layer to which foreign matter relatively hardly sticks and the second substrate are bonded to each other with an adhesive interposed therebetween in step Se. Thus, the method for manufacturing a substrate laminate according to the first embodiment enables suppression of ingress of foreign matter into the substrate laminate.

In addition, in the method for manufacturing a substrate laminate according to the first embodiment, a photosensitive composition containing a curable compound having a cationically polymerizable group and a photocationic polymerization initiator is used, and therefore in step Sb, an exposed portion formed of a semi-cured photosensitive composition can be formed by photocationic polymerization. The semi-cured exposed portion obtained by photocationic polymerization has relatively high adhesion to the first substrate. Thus, the method for manufacturing a substrate laminate according to the first embodiment enables enhancement of adhesiveness between the substrates.

In the first embodiment, the reaction ratio is preferably 95% or more, more preferably 97% or more, still more preferably 99% or more for further suppressing ingress of foreign matter into the substrate laminate. The upper limit of the reaction ratio is not particularly limited, and may be 100%. The reaction ratio can be adjusted by, for example, changing at least one of the type of curable compound, the type of photocationic polymerization initiator, the amount of the photocationic polymerization initiator with respect to the curable compound, and the exposure condition (specifically, integrated exposure amount or the like).

The method for manufacturing a substrate laminate according to the first embodiment may further include a step Sf1 of dicing laminated product of the first substrate and the first layer to obtain a singulated laminated product after step Sd and before step Se. When the method for manufacturing a substrate laminate according to the first embodiment further includes step Sf1, the first layer of the singulated laminated product and the second substrate are bonded to each other with an adhesive interposed therebetween in step Se.

The method for manufacturing a substrate laminate according to the first embodiment may further include a step Sf2 of dicing the laminated product, in which the first substrate, the first layer, the second layer, and the second substrate are laminated in this order, to obtain a singulated laminated product after step Se.

Configuration of Substrate Laminate Obtained by Manufacturing Method According to First Embodiment

Hereinafter, a configuration of a substrate laminate obtained by the manufacturing method according to the first embodiment (a substrate laminate according to a second embodiment described later) will be described with reference to the drawings as appropriate.

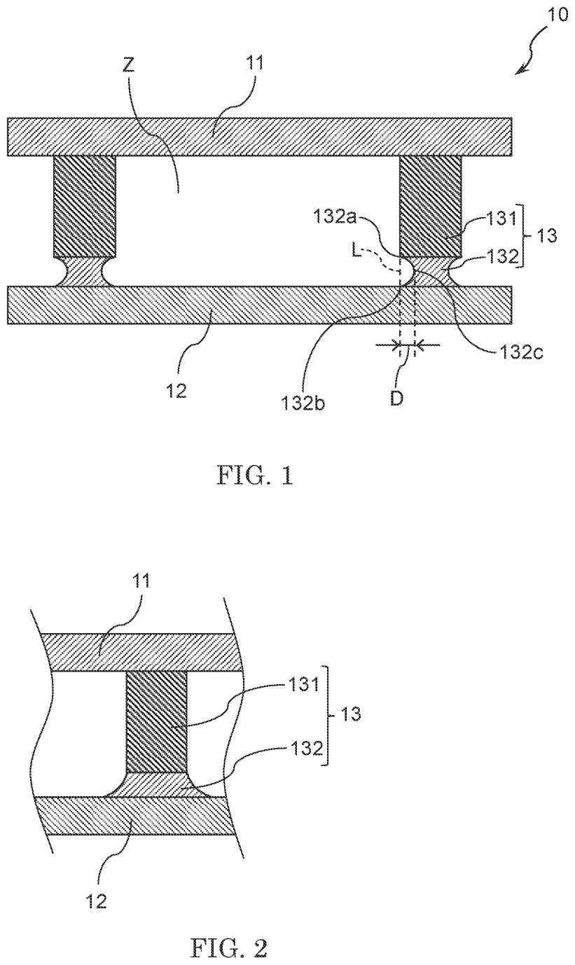

FIG. 1 is a sectional view showing an example of a substrate laminate obtained by the manufacturing method according to the first embodiment. A substrate laminate 10 shown in FIG. 1 includes a first substrate 11, a second substrate 12, and a cured product layer 13 that bonds the first substrate 11 and the second substrate 12. The cured product layer 13 includes a first layer 131 including a cured product of a photosensitive composition and a second layer 132 including a cured product of an adhesive in this order from the first substrate 11 side. The first layer 131 is patterned. The photosensitive composition which is a constituent material for the first layer 131 contains a curable compound having a cationically polymerizable group and a photocationic polymerization initiator, and has alkali solubility. In the substrate laminate 10 shown in FIG. 1, the width of the first substrate 11 and the width of the second substrate 12 are substantially equal to each other, but in the present invention, the width of the first substrate and the width of the second substrate may be different from each other.

The substrate laminate 10 is a hollow structure having a hollow portion Z surrounded by the first substrate 11, the second substrate 12, and the cured product layer 13. The hollow portion Z may be a sealed space. When the substrate laminate 10 forms an image sensor, and the hollow portion Z is a sealed space, the cured product layer 13 functions as a partition wall that prevents ingress of moisture and dust into effective pixel regions.

The second layer 132 is obtained by, for example, curing the adhesive by heating or an ultraviolet ray without passing through a step of patterning by photolithography. An adhesive is normally reduced in volume during curing (shrunk on curing), but since the adhesive in the vicinity of the interface with the first layer 131 and the adhesive in the vicinity the interface with the second substrate 12 are fixed to adjacent layers, the wall surface of the second layer 132 which is obtained by curing the adhesive is usually a curved surface as shown in FIG. 1. On the other hand, as described later, the first layer 131 is a layer obtained by heating the patterned coating film to further cure the semi-cured photosensitive composition in step Sd. Since an end surface (a surface on a side opposite to the first substrate 11 side) of the first layer 131 is not fixed in the curing step, the wall surface of the first layer 131 is usually a flat surface.

For obtaining a substrate laminate further excellent in adhesiveness between substrates, it is preferable to provide the second layer 132 formed when the adhesive is cured to a greater degree (shrunk on curing to a greater degree). On the other hand, for obtaining a substrate laminate excellent in reliability evaluated in a thermal shock test, it is preferable that the concaveness degree of the wall surface of the second layer 132 is small (curing shrinkage is small).

Hereinafter, an example of an index of concaveness degree of the wall surface of the second layer 132 will be described. In a cross-section of the second layer 132 in a width direction (FIG. 1), the concaveness degree of the wall surface of the second layer 132 increases as a shortest distance D from a straight line L passing through both end portions (end portions 132a and 132b) of the wall surface of the second layer 132 in a height direction to a most concave portion 132c of the wall surface of the second layer 132 becomes larger. Hereinafter, the shortest distance from a straight line passing through both ends of the wall surface of the second layer in the height direction to the most concave portion of the wall surface of the second layer is sometimes referred to simply as the “shortest distance D.” For obtaining a substrate laminate excellent in reliability evaluated in a thermal shock test while having further excellent adhesiveness between substrates, the shortest distance D is preferably 0.5 μm or more and 100 μm or less, more preferably 0.5 μm or more and 80 μm or less, still more preferably 1 μm or more and 50 μm or less, even more preferably 1 μm or more and 20 μm or less, particularly preferably 1 μm or more and 10 μm or less. The shortest distance D can be adjusted by, for example, changing at least one of the type of adhesive used and the condition for curing the adhesive (heating condition, ultraviolet irradiation conditions or the like).

The cross-sectional shape of the second layer 132 is not limited to the shape shown in FIG. 1. For example, as shown in FIG. 2, the width of the surface on the second substrate 12 side may be larger than the width of the surface on the first layer 131 side. The width of the surface on the first layer 131 side may be larger than the width of the surface on the second substrate 12 side.

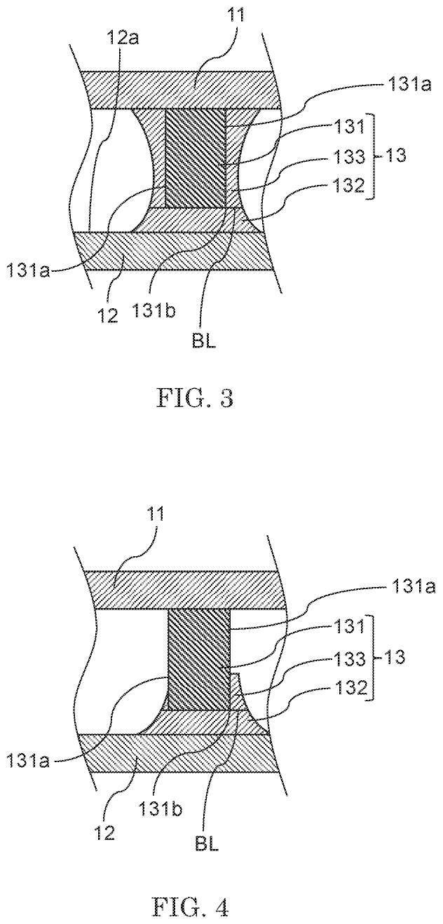

As shown in FIG. 3, the cured product layer 13 may further include a covering layer 133 that covers a wall surface 131a of the first layer 131. Here, it is preferable that the covering layer 133 and the second layer 132 are integrated. When the cured product layer 13 further includes the covering layer 133 covering the wall surface 131a of the first layer 131, and the covering layer 133 and the second layer 132 are integrated, it is possible to obtain a substrate laminate excellent in reliability evaluated in a thermal shock test. For obtaining a substrate laminate further excellent in reliability evaluated in a thermal shock test, the thickness of the covering layer 133 (the height from the wall surface 131a of the first layer 131) is preferably 0.1 μm or more and 1,000 μm or less. Examples of the method for integrally forming the covering layer 133 and the second layer 132 include a method in which an adhesive is applied to at least a part of the wall surface 131a of the first layer 131 and an end surface of the first layer 131 (a surface on a side opposite to the first substrate 11 side), and the first layer 131 and the second substrate 12 are then bonded to each other with the adhesive interposed therebetween to cure the adhesive in step Se described later. Herein, when the covering layer 133 and the second layer 132 are integrated, the covering layer 133 is on the first substrate 11 side and the second layer 132 is on the second substrate 12 side with respect to a line BL which passes through a corner portion 131b of the first layer 131 on the second layer 132 side and is parallel to a surface 12a of the second substrate 12 on the first substrate 11 side, in a cross-section of the cured product layer 13 (FIG. 3). The boundary line (line BL) is shown in FIG. 3 for easy understanding, but when the covering layer 133 and the second layer 132 are integrated, the boundary between the covering layer 133 and the second layer 132 cannot be confirmed in, for example, an electron microscope image. That is, the phrase “the covering layer 133 and the second layer 132 are integrated” means that the covering layer 133 and the second layer 132 are in contact with each other and a boundary therebetween cannot be confirmed in an electron microscope image.

The covering layer 133 is not required to cover the entire surface of the wall surface 131a of the first layer 131. For example, as shown in FIG. 4, the covering layer 133 may cover apart of the wall surface 131a of the first layer 131. When the covering layer 133 covers at least apart of the wall surface 131a of the first layer 131, and the covering layer 133 and the second layer 132 are integrated, it is possible to obtain a substrate laminate excellent in reliability evaluated in a thermal shock test. In particular, when the wall surface 131a in the vicinity of the corner portion 131b of the first layer 131 on the second layer 132 side is covered, the reliability can be enhanced. For obtaining a substrate laminate further excellent in reliability evaluated in a thermal shock test, the height of the covering layer 133 (height from the line BL) is preferably 1 μm or more.

### Steps of Method for Manufacturing Substrate Laminate According to First Embodiment

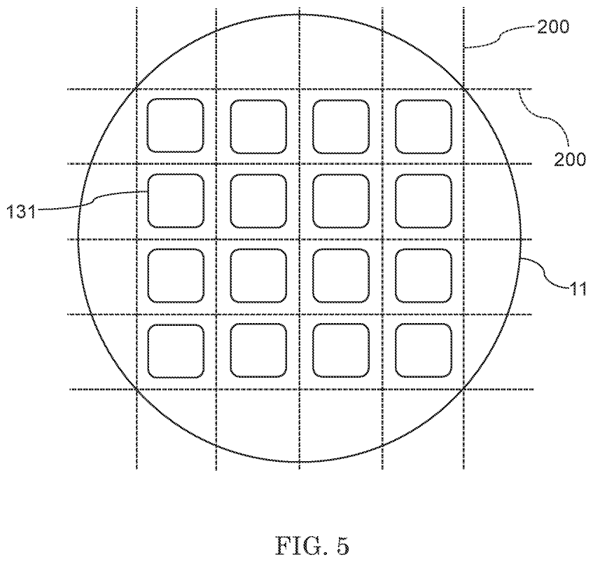

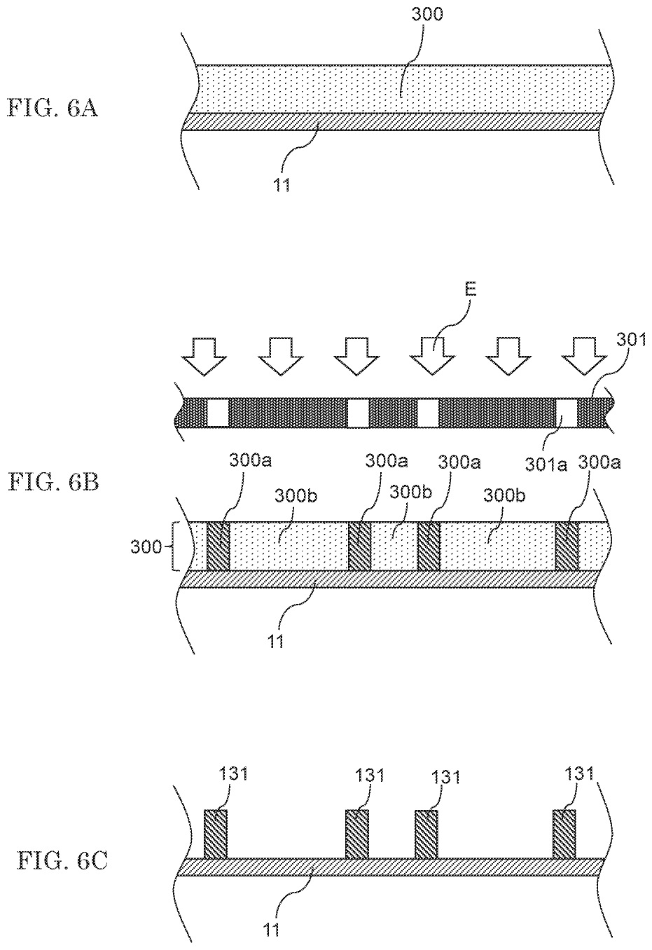

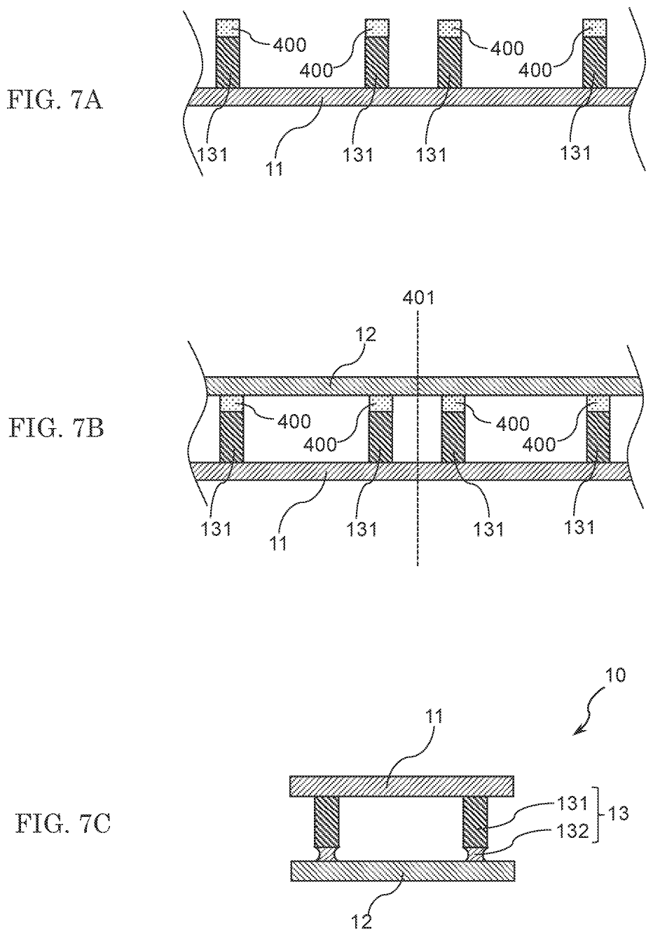

Next, the steps of the method for manufacturing the substrate laminate according to the first embodiment will be described as appropriate with reference to the drawings. FIG. 5 referred here is a plan view showing a first substrate after formation of a first layer in manufacture of an example of the substrate laminate according to the first embodiment. FIGS. 6A to 6C and 7A to 7C are step by step sectional views showing an example of the method for manufacturing a substrate laminate according to the first embodiment.

In an example of the manufacturing method according to the first embodiment, first, a large number of patterned first layers 131 each having a quadrangle-cylindrical shape are formed on a large-sized first substrate 11 (FIG. 5). The pattern of the first layer 131 is not limited to the pattern shown in FIG. 5, and may be designed on the basis of an intended shape. The pattern may have a grid shape or the like. The patterned first layer 131 shown in FIG. 5 can be formed by steps Sa to Sd described in detail below.

(Step Sa)

In step Sa, a photosensitive composition is applied to one surface of the large-sized first substrate 11 to form a coating film 300 formed of the photosensitive composition on the surface of the first substrate 11 (FIG. 6A). The method for application here is not particularly limited, and for example, a general application method such as a spin coating method, a slit coating method, a roll coating method, a printing method, or a bar coating method can be used. The thickness of the coating film 300 is, for example, 0.05 μm or more and 1,000 μm or less, preferably 0.1 μm or more and 500 μm or less, more preferably 1 μm or more and 300 μm or less. In step Sa, the coating film 300 may be heated to remove the solvent in the coating film 300.

(Step Sb)

In step Sb, the coating film 300 is irradiated with an active energy ray E through a photomask 301 to form an exposed portion 300a formed of the semi-cured photosensitive composition and a non-exposed portion 300b in the coating film 300 (FIG. 6B). Transparent area 301a is formed at a location corresponding to the exposed portion 300a of the photomask 301. In this way, only the coating film 300 (exposed portion 300a) located below the transparent area 301a is exposed, and undergoes a photocuring reaction. The integrated exposure amount during exposure is not particularly limited, and is preferably 1 mJ/cm² or more and 10,000 mJ/cm² or less, more preferably 1 mJ/cm² or more and 4,000 mJ/cm² or less. The wavelength of the active energy ray E applied in step Sb in the range of, for example, 200 nm or more and 450 nm or less. Examples of the active energy ray E source include high pressure mercury lamps, ultra-high pressure mercury lamps, metal halide lamps, high power metal halide lamps, xenon lamps, carbon arc lamps, or light emitting diodes. The time of irradiation with the active energy ray E is preferably 1 second or more and 600 seconds or less, more preferably 1 second or more and 150 seconds or less.

(Step Sc)

In step Sc, the non-exposed portion 300b is removed from the first substrate 11 (developed) with an alkaline developer to form a patterned coating film (pattern film) on the first substrate 11. The alkaline developer liquid used in step Sc is, for example, an aqueous solution containing an alkali component. Examples of the alkali component include alkali organic components and alkali inorganic components. Examples of the alkali organic component include tetramethylammonium hydroxide (TMAH) and choline. Examples of the alkali inorganic component include potassium hydroxide, sodium hydroxide, potassium carbonate, sodium carbonate, and lithium carbonate. For increasing the contrast between the exposed portion 300a and the non-exposed portion 300b, the concentration of the alkali component in the alkaline developer is preferably 25 mass % or less, more preferably 10 mass % or less, still more preferably 5 mass % or less. The method for removing the non-exposed portion 300b from the first substrate 11 with the alkaline developer is not particularly limited, and examples thereof include a method in which the alkaline developer is brought into contact with the coating film 300 by an immersion method, a spray method or a paddle method to dissolve and remove the non-exposed portion 300b.

In step Sc, the coating film 300 may be washed with water after the alkaline developer is brought into contact with the coating film 300. When the coating film 300 is washed with water, it is preferable to remove moisture on the surface of the coating film 300 with compressed air after washing with water.

(Step Sd)

In step Sd, the pattern film formed in step Sc (film formed of a semi-cured photosensitive composition) is heated to further cure the semi-cured photosensitive composition, thereby obtaining the first layer 131 including a patterned cured product (FIG. 6C). In this way, a large number of patterned first layers 131 are formed on the large-sized first substrate 11 as shown in FIG. 5. The temperature at which the pattern film is heated in step Sd is preferably 80° C. or higher and 350° C. or lower, more preferably 150° C. or higher and 250° C. or lower.

In the first embodiment, the first layer 131 to which foreign matter relatively hardly adheres is obtained because the semi-cured photosensitive composition is further cured by step Sd. Thus, according to the first embodiment, it is possible to obtain a substrate laminate in which generation of cracks by foreign matter hardly occurs in a thermal shock test. Thus, the substrate laminate obtained by the manufacturing method according to the first embodiment is excellent in reliability evaluated in a thermal shock test.

Step Se is carried out after step Sd. The content of the alkali component in the first layer 131 before step Se is carried out (before step Se) is preferably 1,000 ppm or less, more preferably 200 ppm or less, still more preferably 150 ppm or less. The lower limit of the content of the alkali component in the first layer 131 before step Se is not particularly limited, and is, for example, 1 ppm or more. When in step Se, the first substrate 11 and the second substrate 12 are laminated to form, for example, a hollow structure having a hollow portion Z as shown in FIG. 1, the amount of the alkali component (outgas) released into the hollow portion Z in step Se can be reduced if the content of the alkali component in the first layer 131 before step Se is 1,000 ppm or less. When the substrate laminate forms an image sensor, the function as an image sensor may be deteriorated if the amount of outgas released into the hollow portion Z excessively increases. If the amount of outgas released into the hollow portion Z excessively increases, storage stability at a high temperature and a high humidity (ability to suppress an increase in the amount of foreign matter even during storage at a high temperature and a high humidity) may be deteriorated. Since at least a part of the alkali component in the first layer 131 can be removed in heating of the pattern film in step Sd, the content of the alkali component in the first layer 131 before step Se can be adjusted by changing the heating condition in step Sd. It is also possible to adjust the content of the alkali component in first layer 131 before step Se by changing the formulation of the photosensitive composition used. The method for measuring the content of the alkali component in the first layer 131 before step Se is identical or similar to that in examples described later.

The softening point of the first layer 131 before step Se is preferably 100° C. or higher, more preferably 150° C. or higher. The upper limit of the softening point of the first layer 131 before step Se is not particularly limited, and is, for example, 250° C. or lower. When the softening point of the first layer 131 before step Se is 100° C. or higher, the adherence of foreign matter to the first layer 131 before step Se can be further suppressed. The softening point of the first layer 131 before step Se can be adjusted by, for example, changing heating conditions in step Sd. The method for measuring the softening point the first layer 131 before step Se is identical or similar to that in examples described later.

The elastic modulus of the first layer 131 measured at a temperature of 100° C. by a nanoindentation test method (hereinafter sometimes referred to simply as an “elastic modulus of the first layer 131”) before step Se is preferably 1,500 N/mm² or more, more preferably 2,000 N/mm² or more. The upper limit of the elastic modulus of the first layer 131 is not particularly limited, and is, for example, 5,000 N/mm² or less. When the elastic modulus of the first layer 131 is 1,500 N/mm² or more, the adherence of foreign matter to the first layer 131 before step Se can be further suppressed. The elastic modulus of the first layer 131 can be adjusted by, for example, changing heating conditions in step Sd. The method for measuring the elastic modulus of the first layer 131 is identical or similar to that in examples described later.

(Step Se)

In step Se, the first layer 131 and the second substrate 12 are bonded to each other with an adhesive 400 (see FIG. 7A) interposed therebetween, the adhesive 400 is then cured to obtain the second layer 132 (see FIG. 7C) that bonds the first layer 131 and the second substrate 12. Specifically, first, the adhesive 400 is applied onto the first layer 131 with a syringe or the like as shown in FIG. 7A. In the example shown in FIG. 7A, the adhesive 400 is applied to a surface (end surface) of the first layer 131 on a side opposite to the first substrate 11 side, but the present invention is not limited thereto, and the adhesive 400 may be applied to the second substrate 12, or the adhesive 400 may be applied to both the first layer 131 and the second substrate 12. The adhesive 400 may be applied to at least a part of the wall surface and the end surface of the first layer 131. The method for applying the adhesive 400 is not limited to the method using a syringe, and the adhesive 400 may be applied by, for example, a screen printing method, a stamping method, or the like.

Subsequently, the first layer 131 and the large-sized second substrate 12 are bonded to each other with the adhesive 400 interposed therebetween (FIG. 7B). Subsequently, the adhesive 400 is cured to obtain the second layer 132 (see FIG. 7C) that bonds the first layer 131 and the second substrate 12. The method for curing the adhesive 400 may be appropriately selected according to the type of the adhesive 400. Specific examples of the method for curing the adhesive 400 include a method for curing by heating and a method for curing by ultraviolet irradiation.

(Step Sf2)

In step Sf2, a laminated product in which the large-sized first substrate 11, the first layer 131, the second layer 132, and the large-sized second substrate 12 are laminated in this order are diced to obtain a singulated laminated product after step Se. For example, the adhesive 400 in the laminated product shown in FIG. 7B is cured by step Se, and the laminated product is then diced along a division line 401 of FIG. 7B to obtain the substrate laminate 10 which is a singulated laminated product (FIG. 7C).

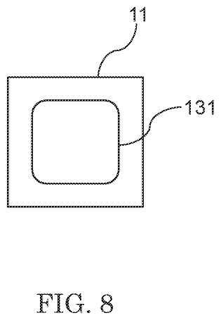

The method shown in FIGS. 7A to 7C includes step Sf2, but the manufacturing method according to the first embodiment is not limited thereto. For example, the manufacturing method according to the first embodiment may further include step Sf1 of dicing the laminated product of the large-sized first substrate 11 and the first layer 131 along with a division line 200 of FIG. 5 to obtain a singulated laminated product (hereinafter, sometimes referred to as a “singulation laminated product”) of FIG. 8 after step Sd and before Se. The singulation laminated product shown in FIG. 8 includes the singulated first substrate 11 and one first layer 131. When the method for manufacturing a substrate laminate according to the first embodiment further includes step Sf1, step Sf2 is not carried out. When the method for manufacturing a substrate laminate according to the first embodiment further includes step Sf1, the first layer 131 of the singulation laminated product and the second substrate 12 are bonded to each other with an adhesive 400 interposed therebetween in step Se.

When the manufacturing method according to the first embodiment further includes step Sf1, the adhesive 400 may be cured after a plurality of first layers 131 of the singulation laminated product and the large-sized second substrate 12 are bonded to each other with the adhesive 400 interposed therebetween in step Se. Here, a plurality of substrate laminates can be obtained by cutting the large-sized second substrate 12 is cut between the first layers 131 after the adhesive 400 is cured.

### Elements of Substrate Laminate Obtained by Manufacturing Method According to First Embodiment

Next, the elements of the substrate laminate obtained by manufacturing method according to first embodiment will be described.

(First Substrate and Second Substrate)

Examples of the first substrate and the second substrate include silicon wafers, glass substrates, resin substrates (transparent resin substrates and the like), ceramic substrates, and semiconductor element substrates. Examples of the semiconductor element substrate include sensor substrates (more specifically, image sensor substrates and the like). The types of the first substrate and the second substrate may the same or different. When one of the first substrate and the second substrate is a transparent substrate (more specifically, a glass substrate, a transparent resin substrate, or the like), the substrate laminate can be applied to a constituent member of an optical component. In particular, a substrate laminate in which one of the first substrate and the second substrate is a transparent substrate and the other is a semiconductor element substrate is suitable for image sensors.

The thickness of each of the first substrate and the thickness of the second substrate is, for example, 50 μm or more and 2,000 μm or less. When one of the first substrate and the second substrate is a semiconductor element substrate, the thickness of the semiconductor element substrate is, for example, 50 μm or more and 800 μm or less. The thickness of the first substrate and the thickness of the second substrate may be the same or different.

(First Layer)

The first layer includes a cured product of a photosensitive composition. Details of the photosensitive composition as a material for the first layer will be described later. For obtaining a substrate laminate excellent in reliability evaluated in a thermal shock test, the height (thickness) of the first layer is preferably 500 μm or less, more preferably 400 μm or less, still more preferably 300 μm or less, even more preferably 150 μm or less, and may be 140 μm or less, 130 μm or less, 120 μm or less, 110 μm or less, or 100 μm or less. For suppressing reflection of foreign matter adhered to the transparent substrate in application of the substrate laminate to an image sensor, the height of the first layer is preferably 10 μm or more, more preferably 15 μm or more, still more preferably 20 μm or more, even more preferably 30 μm or more, and may be 40 μm or more. The width of the first layer is, for example, 10 μm or more and 500 μm or less, preferably 10 μm or more and 200 μm or less, more preferably 20 μm or more and 150 μm or less.

(Second Layer)

The second layer includes a cured product of an adhesive. Examples of the adhesive as a material for the second layer include thermosetting adhesives (more specifically, epoxy adhesives and the like), and ultraviolet-curable adhesives (More specifically, acryl-based adhesives and the like). The term “acryl-based adhesive” means an adhesive containing (meth)acrylic acid or a derivative thereof (more specifically, (meth)acrylic acid ester or the like) or a polymer of (meth)acrylic acid or a derivative thereof as a main component.

For obtaining a substrate laminate further excellent in adhesiveness between substrates, the adhesive as a material for the second layer is preferably an epoxy-based adhesive. When an epoxy-based adhesive is used as an adhesive as a material for the second layer, the main agent of the epoxy-based adhesive is preferably an aromatic epoxy compound having two or more epoxy groups, more preferably a bisphenol-based diglycidyl ether (more specifically, bisphenol A diglycidyl ether, bisphenol F diglycidyl ether, bisphenol S diglycidyl ether, or the like), still more preferably bisphenol A diglycidyl ether for obtaining a substrate laminate further excellent in adhesiveness between substrates.

When an epoxy-based adhesive is used as an adhesive as a material for the second layer, the curing agent for the epoxy-based adhesive is preferably an imidazole-based curing agent for obtaining a substrate laminate further excellent in adhesiveness between substrates.

For obtaining a substrate laminate further excellent in adhesiveness between substrates, the adhesive as a material for the second layer is preferably an epoxy-based adhesive containing bisphenol-based diglycidyl ether as a main agent and an imidazole-based curing agent as a curing agent, more preferably an epoxy-based adhesive containing bisphenol A diglycidyl ether as a main agent and an imidazole-based curing agent as a curing agent. Here, the mass ratio of the main agent to the curing agent (main agent/curing agent) in the epoxy-based adhesive is, for example, 100/10 or more and 100/1 or less.

For obtaining a substrate laminate which is excellent in adhesiveness between substrates and also excellent in reliability evaluated in a thermal shock test, the height (thickness) of the second layer is preferably 0.01 μm or more and 100 μm or less, more preferably 0.1 μm or more and 80 μm or less, still more preferably 0.5 μm or more and 50 μm or less, even more preferably 1 μm or more and 20 μm or less. The width of the second layer can be appropriately changed according to the width of the first layer, and is, for example, 10 μm or more and 500 μm or less, preferably 10 μm or more and 200 μm or less, more preferably 20 μm or more and 150 μm or less. For obtaining a substrate laminate further excellent in reliability evaluated in a thermal shock test, the width of the second layer when the width of the first layer which is defined as 100% is preferably 70% or more, more preferably 80% or more, still more preferably 90% or more, and may be 100% or more, 110% or more, or 120% or more.

[Photosensitive Composition]

Next, the photosensitive composition as a material for the first layer will be described. The photosensitive composition as a material for the first layer contains a curable compound having a cationically polymerizable group and a photocationic polymerization initiator, and has alkali solubility.

Examples of the cationically polymerizable group include an epoxy group, a vinyl ether group, an oxetanyl group, and an alkoxysilyl group. From the viewpoint of the storage stability of the photosensitive composition, the cationically polymerizable group is preferably one or more selected from the group consisting of a glycidyl group, an alicyclic epoxy group and an oxetanyl group, more preferably one or more selected from the group consisting of a glycidyl group and an alicyclic epoxy group. Among them, an alicyclic epoxy group is particularly preferable because it is excellent in photocationic polymerizability.

When the photosensitive composition as a material for the first layer contains a curable compound having one or more selected from the group consisting of a glycidyl group and an alicyclic epoxy group, the first substrate is preferably a glass substrate. Since both a glycidyl group and an alicyclic epoxy group have good bondability to a surface of the glass substrate, it is possible to obtain a substrate laminate further excellent in adhesiveness between substrates when the photosensitive composition as a material for the first layer contains a curable compound having one or more selected from the group consisting of a glycidyl group and an alicyclic epoxy group, and the first substrate is a glass substrate.

When the photosensitive composition as a material for the first layer contains a curable compound having one or more selected from the group consisting of a glycidyl group and an alicyclic epoxy group, it is preferable to use an epoxy-based adhesive as an adhesive as a material for the second layer in order to improve bonding strength between the first layer and the second layer.

Examples of the curable compound having a cationically polymerizable group include polysiloxane compounds having a cationically polymerizable group, bisphenol A type epoxy resins, hydrogenated bisphenol A type epoxy resins, novolac phenol type epoxy resins, biphenyl type epoxy resins, dicyclopentadiene type epoxy resins, bisphenol F diglycidyl ether, bisphenol A diglycidyl ether, 2,2′-bis(4-glycidyloxycyclohexyl)propane, vinylcyclohexene dioxide, 2-(3,4-epoxycyclohexyl)-5,5-spiro-(3,4-epoxycyclohexane)-1,3-dioxane, bis(3,4-epoxycyclohexyl)adipate, 1,2-cyclopropanedicarboxylic acid bisglycidyl esters, triglycidyl isocyanurate, monoallyl diglycidyl isocyanurate, diallyl monoglycidyl isocyanurate, 3-ethyl-3-(phenoxymethyl)oxetane, 3,4-epoxycyclohexylmethyl 3,4-epoxycyclohexanecarboxylate (“CELLOXIDE (registered trademark) 2021 P” manufactured by DAICEL CORPORATION), and ε-caprolactone-modified 3′,4′-epoxycyclohexylmethyl 3,4-epoxycyclohexanecarboxylate (“CELLOXIDE (registered trademark) 2081” manufactured by DAICEL CORPORATION).

The photosensitive composition as a material for the first layer has alkali solubility due to the presence of a compound having an alkali-soluble group. Examples of the compound having an alkali-soluble group include polysiloxane compounds having an alkali-soluble group, resins having a phenolic hydroxyl group (for example, novolac-based resins having a phenolic hydroxyl group), and resins having a carboxy group (for example, copolymers of (meth)acrylic acid and (meth)acrylic acid ester).

For enabling the formation of a first layer excellent in heat resistance and obtaining a substrate laminate excellent in storage stability at a high temperature and a high humidity, it is preferable that the photosensitive composition as a material for the first layer contains a polysiloxane compound having a cationically polymerizable group as the curable compound having a cationically polymerizable group. For forming a first layer excellent in heat resistance while improving the patterning property, it is preferable that the photosensitive composition as a material for the first layer contains a polysiloxane compound having a cationically polymerizable group and an alkali-soluble group in one molecule as a compound serving as both the curable compound having a cationically polymerizable group and the compound having an alkali-soluble group. That is, for forming a first layer excellent in heat resistance while improving the patterning property, it is preferable that the photosensitive composition as a material for the first layer contains a polysiloxane compound having a cationically polymerizable group and an alkali-soluble group in one molecule (hereinafter, sometimes referred to as “component (A)”), and a photocationic polymerization initiator (hereinafter, sometimes referred to as “component (B)”). Hereinafter, the photosensitive composition containing the component (A) and the component (B) is sometimes referred to as a “specific photosensitive composition.” Hereinafter, components contained in the specific photosensitive composition will be described in detail.

{Component (A)}

The component (A) is not particularly limited as long as it is a polysiloxane compound having a cationically polymerizable group and an alkali-soluble group in one molecule. When the component (A) has a cationically polymerizable group and an alkali-soluble group in one molecule, a specific photosensitive composition excellent in both developability and curability can be obtained. Preferably, the component (A) has a plurality of cationically polymerizable groups in one molecule. When the component (A) has a plurality of cationically polymerizable groups in one molecule, there is a tendency that a first layer having a high crosslinking density is obtained, resulting in further improvement of the heat resistance of the first layer. A plurality of cationically polymerizable groups may be the same, or two or more different functional groups. Preferably, the component (A) has a plurality of alkali-soluble groups in one molecule. When the component (A) has a plurality of alkali-soluble groups in one molecule, developability tends to be further improved because non-exposed portion removability is enhanced during development. A plurality of alkali-soluble groups may be the same, or two or more different functional groups.

The component (A) may have a chain polysiloxane structure or a cyclic polysiloxane structure. For forming the first layer having further excellent heat resistance, it is preferable that the component (A) has a cyclic polysiloxane structure. When the component (A) has a cyclic polysiloxane structure, the specific photosensitive composition tends to have high film formability and developability.

The component (A) may have a polysiloxane structure in the main chain or a polysiloxane structure in the side chain. For forming a first layer having further excellent heat resistance, it is preferable that the component (A) has a polysiloxane structure in the main chain. For forming a first layer having furthermore excellent heat resistance, it is preferable that the component (A) has a cyclic polysiloxane structure in the main chain.

The cyclic polysiloxane structure may be a monocyclic structure or a polycyclic structure. The polycyclic structure may be a polyhedral structure. A first layer having high hardness and excellent heat resistance tends to be obtained when the content of T units (XSiO_{3/2}) or the Q units (SiO_{4/2}) among siloxane units forming a ring is high. A first layer which is more flexible and has reduced residual stress tends to be obtained when the content of M units (X₃SiO_{1/2}) or the D units (X₂SiO_{2/2}) is high.

When the component (A) is a polymer having a polysiloxane structure in the main chain, the weight average molecular weight of the polymer is preferably 10,000 or more and 50,000 or less, and more preferably 20,000 or more and 40,000 or less. When the weight average molecular weight is 10,000 or more, the heat resistance of the obtained first layer tends to be further improved. On the other hand, when the weight average molecular weight is 50,000 or less, developability tends to be further improved.

Examples of the cationically polymerizable group of the component (A) include an epoxy group, a vinyl ether group, an oxetanyl group, and an alkoxysilyl group. From the viewpoint of the storage stability of the specific photosensitive composition, the cationically polymerizable group is preferably one or more selected from the group consisting of a glycidyl group, an alicyclic epoxy group and an oxetanyl group, more preferably one or more selected from the group consisting of a glycidyl group and an alicyclic epoxy group. Among them, an alicyclic epoxy group is particularly preferable because it is excellent in photocationic polymerizability.

The alkali-soluble group of the component (A) is preferably one or more selected from the group consisting of a monovalent organic group represented by the following chemical formula (X1) (hereinafter, sometimes referred to as an “X1 group”), a divalent organic group represented by the following chemical formula (X2) (hereinafter, sometimes referred to as an “X2 group”), a phenolic hydroxyl group, and a carboxy group. The X1 group is a monovalent organic group derived from a N-mono-substituted isocyanuric acid. The X2 group is a divalent organic group derived from a N,N-disubstituted isocyanuric acid.

Chemical Formula X1 and X2

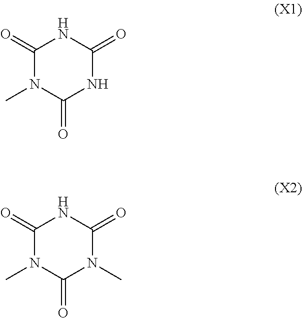

For forming a first layer having further excellent heat resistance, the alkali-soluble group of the component (A) is preferably one or more selected from the group consisting of the X1 group and the X2 group.

The method for introducing the cationically polymerizable group into the polysiloxane compound is not particularly limited, and a method using a hydrosilylation reaction is preferable because a cationically polymerizable group can be introduced into a polysiloxane compound via a chemically stable silicon-carbon bond (Si—C bond). In other words, the component (A) is preferably a polysiloxane compound which is organically modified by a hydrosilylation reaction and into which a cationically polymerizable group is introduced via a silicon-carbon bond. Preferably, the alkali-soluble group is also introduced into the polysiloxane compound via a silicon-carbon bond by a hydrosilylation reaction.

The component (A) is obtained by, for example, a hydrosilylation reaction using the following compounds (α), (β), and (γ) as starting substances.
Compound (α): Polysiloxane compound having at least two SiH groups (hydrosilyl groups) in one molecule.
Compound (β): Compound having a carbon-carbon double bond having reactivity with SiH group and a cationically polymerizable group in one molecule.
Compound (γ): Compound having a carbon-carbon double bond having reactivity with a SiH group and an alkali-soluble group in one molecule.

(Compound (α))

The compound (α) is a polysiloxane compound having at least two SiH groups in one molecule, and it is possible to used, for example, a compound disclosed in WO 96/15194, which has at least two SiH groups in one molecule. Specific examples of the compound (α) include hydrosilyl group-containing polysiloxanes having a linear structure, polysiloxanes having a hydrosilyl group at a molecular terminal, and a cyclic polysiloxanes containing a hydrosilyl group (hereinafter, sometimes referred to simply as “cyclic polysiloxane”). The cyclic polysiloxane may have a polycyclic structure, and the polycyclic structure may be a polyhedral structure. For forming a first layer having high heat resistance and mechanical strength, it is preferable that a cyclic polysiloxane compound having at least two SiH groups in one molecule is used as the compound (α). The compound (α) is preferably a cyclic polysiloxane having three or more SiH groups in one molecule. From the viewpoint of heat resistance and light resistance, the group present on the Si atom is preferably a hydrogen atom or a methyl group.

Examples of the hydrosilyl group-containing polysiloxane having a linear structure include a copolymers of a dimethylsiloxane unit with a methylhydrogensiloxane unit and a terminal trimethylsiloxy unit, copolymers of a diphenylsiloxane unit with a methylhydrogensiloxane unit and a terminal trimethylsiloxy unit, copolymers of a methylphenylsiloxane unit with a methylhydrogensiloxane unit and a terminal trimethylsiloxy unit, and polysiloxanes terminally blocked with a dimethylhydrogensilyl group.

Examples of the polysiloxane having a hydrosilyl group at a molecular terminal include polysiloxanes terminally blocked with a dimethylhydrogensilyl group, and polysiloxanes including a dimethylhydrogensiloxane unit (H(CH₃)₂SiO_{1/2} unit) and one or more siloxane units selected from the group consisting of a SiO₂ unit, a SiO_{3/2} unit and a SiO unit.

The cyclic polysiloxane is represented by, for example, the following general formula I.

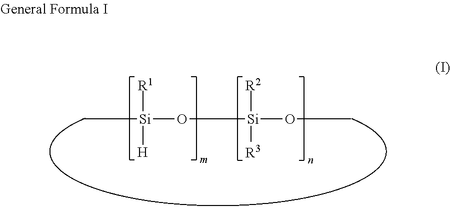

In the general formula I, R¹, R², and R³ each independently represent a monovalent organic group having 1 or more and 20 or less carbon atoms, m represents an integer of 2 or more and 10 or less, and n represents an integer of 0 or more and 10 or less. For easily carrying out the hydrosilylation reaction, m is preferably 3 or more. For easily carrying out the hydrosilylation reaction, m+n is preferably 3 or more and 12 or less. For easily carrying out the hydrosilylation reaction, n is preferably 0.

R¹, R², and R³ are each preferably an organic group having one or more elements selected from the group consisting of C, H, and O. Examples of R¹, R², and R³ include alkyl groups, hydroxyalkyl groups, alkoxyalkyl groups, oxyalkyl groups, and aryl groups. Among them, chain alkyl groups such as a methyl group, an ethyl group, a propyl group, a hexyl group, an octyl group, a decyl group and a dodecyl group; cyclic alkyl groups such as cyclohexyl groups and norbornyl groups; or a phenyl group is preferable. From the viewpoint of availability of the cyclic polysiloxane, R¹, R², and R³ are each preferably a chain alkyl group having 1 or more and 6 or less carbon atoms, or a phenyl group. For easily carrying out the hydrosilylation reaction, R¹, R², and R³ are each preferably a chain alkyl group, more preferably a chain alkyl group having 1 or more and 6 or less carbon atoms, still more preferably a methyl group.

Examples of the cyclic polysiloxane represented by the general formula I include 1,3,5,7-tetrahydrogen-1,3,5,7-tetramethylcyclotetrasiloxane, 1-propyl-3,5,7-trihydrogen-1,3,5,7-tetramethylcyclotetrasiloxane, 1,5-dihydrogen-3,7-dihexyl-1,3,5,7-tetramethylcyclotetrasiloxane, 1,3,5-trihydrogen-1,3,5-trimethylcyclotrisiloxane, 1,3,5,7,9-pentahydrogen-1,3,5,7,9-pentamethylcyclopentasiloxane, and 1,3,5,7,9,11-hexahydrogen-1,3,5,7,9,11-hexamethylcyclohexasiloxane. Among them, 1,3,5,7-tetrahydrogen-1,3,5,7-tetramethylcyclotetrasiloxane (a compound of the general formula I in which m is 4, n is 0, and R¹ is a methyl group) is preferable from the viewpoint of availability, and reactivity of the SiH group.

The compound (α) is obtained by a known synthesis method. The cyclic polysiloxane represented by the general formula I can be synthesized by, for example, a method disclosed in WO 96/15194 A or the like. The cyclic polysiloxane having a polyhedral backbone can be synthesized by, for example, a method described in Japanese Patent Laid-Open Publication No. 2004-359933, Japanese Patent Laid-Open Publication No. 2004-143449, Japanese Patent Application Laid-Open Publication No. 2006-269402, or the like. As the compound (α), a commercially available polysiloxane compound may be used.

For forming a first layer further excellent in heat resistance while enhancing the developability of the specific photosensitive composition, the content of the structural unit derived from the compound (α) in the component (A) is preferably 10 mass % or more and 50 mass % or less, more preferably 15 mass % or more and 45 mass % or less, based on 100 mass % of the component (A).

(Compound (β))

The compound (β) has a carbon-carbon double bond having reactivity with a SiH group (hydrosilyl group) and a cationically polymerizable group in one molecule, and is used for introducing a cationically polymerizable group into a polysiloxane compound. The cationically polymerizable group in the compound (β), together with its preferred aspects, is the same as described above for the cationically polymerizable group of the component (A). That is, the compound (β) has preferably one or more selected from the group consisting of a glycidyl group, an alicyclic epoxy group and an oxetanyl group, more preferably one or more selected from the group consisting of a glycidyl group and an alicyclic epoxy group, still more preferably has an alicyclic epoxy group, as the cationically polymerizable group.

Examples of the group containing a carbon-carbon double bond having reactivity with a SiH group (hereinafter, sometimes referred to simply as an “alkenyl group”) include a vinyl group, an allyl group, a methallyl group, an allyloxy group (—O—CH₂—CH═CH₂), a 2-allylphenyl group, a 3-allylphenyl group, a 4-allylphenyl group, a 2-(allyloxy)phenyl group, a 3-(allyloxy) phenyl group, a 4-(allyloxy)phenyl group, a 2-(allyloxy)ethyl group, a 2,2-bis(allyloxymethyl)butyl group, a 3-allyloxy-2,2-bis (allyloxymethyl)propyl group, and a vinyl ether group. From the viewpoint of reactivity with a SiH group, the compound (β) has preferably one or more selected from the group consisting of a vinyl group, an allyl group and an allyloxy group, more preferably one or more selected from the group consisting of a vinyl group and an allyl group, as the alkenyl group.

Specific examples of the compound (β) include 1-vinyl-3,4-epoxycyclohexane, allyl glycidyl ether, allyl oxetanyl ether, diallyl monoglycidyl isocyanurate, and monoallyl diglycidyl isocyanurate. From the viewpoint of reactivity in cationic polymerization, the compound (β) is preferably a compound having one or more functional groups selected from the group consisting of an alicyclic epoxy group and a glycidyl group, more preferably a compound having an alicyclic epoxy group. For further enhancing the reactivity in cationic polymerization, the compound (β) is preferably one or more compounds selected from the group consisting of allyl glycidyl ether and 1-vinyl-3,4-epoxycyclohexane, more preferably 1-vinyl-3,4-epoxycyclohexane.

For forming a first layer further excellent in heat resistance while enhancing the developability of the specific photosensitive composition, the content of the structural unit derived from the compound (β) in the component (A) is preferably 20 mass % or more and 50 mass % or less, more preferably 22 mass % or more and 45 mass % or less, based on 100 mass % of the component (A).

(Compound (γ))

The compound (γ) has a carbon-carbon double bond having reactivity with a SiH group and an alkali-soluble group in one molecule, and is used for introducing an alkali-soluble group into a polysiloxane compound. The alkali-soluble group in the compound (γ), together with its preferred aspects, is the same as described above for the alkali-soluble group of the component (A). That is, the compound (γ) has preferably one or more selected from the group consisting of an X1 group, an X2 group, a phenolic hydroxyl group and a carboxy group, more preferably one or more selected from the group consisting of an X1 group and an X2 group, as the alkali-soluble group.

The compound (γ) has a group containing a carbon-carbon double bond having reactivity with a SiH group (alkenyl group). Examples of the alkenyl group of the compound (γ), together with its preferred aspects, include those exemplified above for the alkenyl group of the compound (β). That is, the compound (β) has preferably one or more selected from the group consisting of a vinyl group, an allyl group and an allyloxy group, more preferably one or more selected from the group consisting of a vinyl group and an allyl group, as the alkenyl group.

The compound (γ) may have two or more alkenyl groups in one molecule. When the compound (γ) contains a plurality of alkenyl groups in one molecule, a plurality of compounds (α) can be crosslinked by the hydrosilylation reaction, and therefore the crosslinking density of the resulting cured product tends to increase, resulting in improvement of the heat resistance of the cured product.

Specific examples of the compound (γ) include diallyl isocyanurate, monoallyl isocyanurate, 2,2′-diallyl bisphenol A, vinylphenol, allylphenol, butenoic acid, pentenoic acid, hexenoic acid, heptenoic acid, and undecylenic acid.

For obtaining a specific photosensitive composition excellent in developability, the compound (γ) is preferably one or more selected from the group consisting of diallyl isocyanurate, monoallyl isocyanurate and 2,2′-diallyl bisphenol A, more preferably one or more selected from the group consisting of diallyl isocyanurate and monoallyl isocyanurate. When monoallyl isocyanurate is used as the compound (γ), a component (A) having the X1 group as an alkali-soluble group is obtained. When diallyl isocyanurate is used as the compound (γ), a component (A) having the X2 group as an alkali-soluble group is obtained.

For obtaining a specific photosensitive composition further excellent in developability, the content of the structural unit derived from the compound (γ) in the component (A) is preferably 5 mass % or more and 50 mass % or less, more preferably 10 mass % or more and 30 mass % or less, based on 100 mass % of the component (A).

(Other Starting Substances)

In addition to the compound (α), compound (β) and compound (γ), other starting substances may be used in the hydrosilylation reaction. For example, an alkenyl group-containing compound which is different from the compound (β) and compound (γ) (hereinafter, sometimes referred to as “another alkenyl group-containing compound”) may be used as the other starting substance.

For obtaining a first layer further excellent in heat resistance, it is preferable to use a compound having two or more alkenyl groups in one molecule (hereinafter, sometimes referred to as a “compound (δ)”) as another alkenyl group-containing compound. When the compound (δ) is used, the heat resistance of the obtained first layer tends to be further improved because the number of crosslinking points increases during the hydrosilylation reaction.

Specific examples of the compound (δ) include diallyl phthalate, triallyl trimellitate, diethylene glycol bisallyl carbonate, 1,1,2,2-tetraallyloxyethane, triallyl cyanurate, triallyl isocyanurate, diallyl monobenzyl isocyanurate, diallyl monomethyl isocyanurate, 1,2,4-trivinylcyclohexane, triethylene glycol divinyl ether, divinylbenzene, divinylbiphenyl, 1,3-diisopropenylbenzene, 1,4-diisopropenylbenzene, 1,3-bis(allyloxy)adamantane, 1,3-bis(vinyloxy)adamantane, 1,3,5-tris(allyloxy)adamantane, 1,3,5-tris(vinyloxy)adamantane, dicyclopentadiene, vinylcyclohexene, 1,5-hexadiene, 1,9-decadiene, diallyl ether, and oligomers thereof.

For further improving the heat resistance of the resulting first layer, the compound (δ) is preferably one or more selected from the group consisting of triallyl isocyanurate and diallyl monomethyl isocyanurate, more preferably diallyl monomethyl isocyanurate.

For enhancing alkali developability while further improving the heat resistance of the resulting first layer, the content of the structural unit derived from the compound (δ) in the component (A) is preferably 5 mass % or more and 30 mass % or less, more preferably 8 mass % or more and 20 mass % or less, based on 100 mass % of the component (A).

(Hydrosilylation Reaction)

The order and the method of the hydrosilylation reaction for obtaining the component (A) are not particularly limited. For example, the component (A) is obtained by a hydrosilylation reaction conforming to a method disclosed in WO 2009/075233 and using the compound (α), the compound (β), the compound (γ), and other starting substances as optional components if necessary. The component (A) obtained using the compound (α), the compound (β), the compound (γ), and other starting substances as optional components if necessary is, for example, a polymer having a plurality of cationically polymerizable groups and a plurality of alkali-soluble groups in one molecule, and a polysiloxane structure in the main chain.

The proportion of each compound in the hydrosilylation reaction is not particularly limited, but the total amount A of alkenyl groups and the total amount B of SiH groups in the starting substance preferably satisfy 1≤B/A≤30, and more preferably satisfy 1≤B/A≤10.

In the hydrosilylation reaction, a hydrosilylation catalyst such as chloroplatinic acid, a platinum-olefin complex, or a platinum-vinylsiloxane complex may be used. The hydrosilylation catalyst and a co-catalyst may be used in combination. The addition amount (substance amount) of the hydrosilylation catalyst is not particularly limited, and is preferably 10⁻⁸ or more and 10⁻¹ or less times, more preferably 10⁻⁶ or more and 10⁻² or less times the total substance amount of alkenyl groups contained in the starting substance.

The temperature of the hydrosilylation reaction may be appropriately set, and is preferably 30° C. or higher and 200° C. or lower, more preferably 50° C. or higher and 150° C. or lower. The oxygen concentration of the gas phase portion in the hydrosilylation reaction is preferably 3 vol % or less. From the viewpoint of accelerating the hydrosilylation reaction, the gas phase portion may contain oxygen in an amount of 0.1 vol % or more and 3 vol % or less.

A solvent may be used in the hydrosilylation reaction. As the solvent, a single solvent or a mixture of two or more solvents can be used. Examples of the solvent that can be used include hydrocarbon-based solvents such as benzene, toluene, xylene, hexane, and heptane; ether-based solvents such as tetrahydrofuran, 1,4-dioxane, 1,3-dioxolane, and diethyl ether; ketone-based solvents such as acetone and methyl ethyl ketone; halogen-based solvents such as chloroform, methylene chloride, and 1,2-dichloroethane. Toluene, xylene, tetrahydrofuran, 1,4-dioxane, 1,3-dioxolane, or chloroform is preferable because it is easily distilled off after the reaction. In the hydrosilylation reaction, a gelling inhibitor may be used if necessary.

For obtaining a substrate laminate further excellent in adhesiveness between substrates, the content of the component (A) in the specific photosensitive composition is preferably 20 mass % or more and 95 mass % or less based on the total solid content of the specific photosensitive composition.

{Component (B)}

As the component (B), for example, a known photocationic polymerization initiator can be used. The component (B) is not particularly limited, and examples thereof include various compounds which are considered suitable in Japanese Patent Laid-open Publication No. 2000-1648, National Publication of International Patent Application No. 2001-515533, and WO 2002/83764. The component (B) is preferably a sulfonate ester-based compound, a carboxylic acid ester-based compound, or an onium salt-based compound, more preferably an onium salt-based compound, still more preferably a sulfonium salt-based compound.

As the sulfonate ester-based compound, various sulfonic acid derivatives can be used, and examples thereof include disulfone-based compounds, disulfonyldiazomethane-based compounds, disulfonylmethane-based compounds, sulfonylbenzoylmethane-based compounds, imidosulfonate-based compounds, benzoin sulfonate-based compounds, pyrogallol trisulfonate-based compounds, and benzyl sulfonate-based compounds.

Specific examples of the sulfonate ester-based compound include diphenyl disulfone, ditosyl disulfone, bis(phenylsulfonyl)diazomethane, bis(chlorophenylsulfonyl)diazomethane, bis(xylylsulfonyl)diazomethane, phenylsulfonylbenzoyldiazomethane, bis(cyclohexylsulfonyl)methane, 1,8-naphthalenedicarboxylic acid imidomethylsulfonate, 1,8-naphthalenedicarboxylic acid imidotosylsulfonate, 1,8-naphthalenedicarboxylic acid imidotrifluoromethylsulfonate, 1,8-naphthalenedicarboxylic acid imidocamphorsulfonate, succinic acid imidophenylsulfonate, succinic acid imidotosylsulfonate, succinic acid imidotrifluoromethylsulfonate, succinic acid imidocamphorsulfonate, phthalic acid imidotrifluorosulfonate, cis-5-norbornene-endo-2,3-dicarboxylic acid imidotrifluoromethylsulfonate, benzoin tosylate, 1,2-diphenyl-2-hydroxypropyl tosylate, 1,2-di(4-methylmercaptophenyl)-2-hydroxypropyl tosylate, pyrogallol methylsulfonate, pyrogallol ethylsulfonate, 2,6-dinitrophenylmethyl tosylate, o-nitrophenylmethyl tosylate, and p-nitrophenyl tosylate.

These compounds can be used alone, or in combination of two or more thereof. In the present invention, a carboxylic acid ester-based compound can also be used as the component (B).

Examples of the onium salt-based compound include sulfonium salt-based compounds and iodonium salt-based compounds. Examples of the anion of the sulfonium salt-based compound and the iodonium salt-based compound include tetrafluoroborate (BF₄⁻), hexafluorophosphate (PF₆⁻), hexafluoroantimonate (SbF₆⁻), hexafluoroarsenate (AsF₆⁻), hexachloroantimonate (SbCl₆⁻), tetraphenylborate, tetrakis(trifluoromethylphenyl)borate, tetrakis(pentafluoromethylphenyl)borate, fluoroalkylfluorophosphate, perchlorate ions (ClO₄⁻), trifluoromethanesulfonate ions (CF₃SO₃⁻), fluorosulfonate ions (FSO₃⁻), and toluenesulfonate ions.

The photocationic polymerization initiators listed in descending order in terms of acid strength of the acid generated are as follows: compounds containing SbF₆⁻ as an anion, compounds containing B(C₆F₅)₄⁻ as an anion, compounds containing PF₆⁻ as an anion, compounds containing CF₃SO₃⁻ as an anion, and compounds containing HSO₄⁻ as an anion. When a photocationic polymerization initiator which generates an acid having high acid strength is used, the residual film ratio tends to increase. The pKa of the acid generated from the photocationic polymerization initiator is preferably less than 3, more preferably less than 1.

Examples of the cation of the sulfonium salt-based compound include cations represented by the following chemical formula II and cations represented by the following general formula III. R⁴, R⁵ and R⁶ each independently represent an alkyl group.

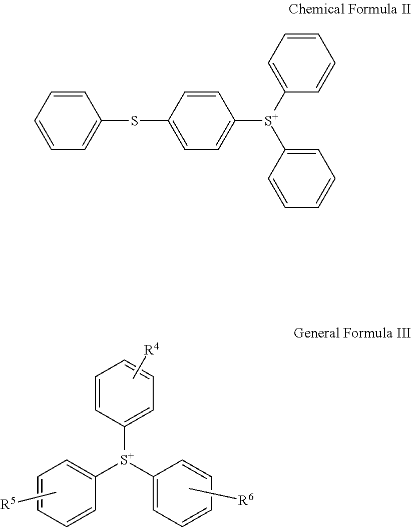

Examples of the commercially available product of the sulfonium salt-based compound (sulfonium salt-based photocationic polymerization initiator) include a photocationic polymerization initiator containing a fluoroalkyl fluorophosphate (anion) and a cation represented by chemical formula II (“CPI-210S” manufactured by San-Apro Ltd).

Examples of the cation of the iodonium salt-based compound include cations represented by the following general formula IV. R⁷ and R⁸ in the following general formula IV each independently represent an alkyl group.

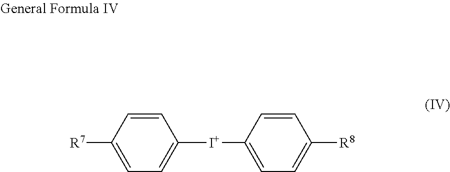

The content of the component (B) in the specific photosensitive composition is not particularly limited. From the viewpoint of the balance between the curing rate and the physical properties of the cured product, the content of the component (B) is preferably 0.1 parts by mass or more and 20 parts by mass or less, more preferably 0.5 parts by mass or more and 10 parts by mass or less, based on 100 parts by mass of the component (A).

{Solvent}

The specific photosensitive composition may contain a solvent. For example, the component (A), the component (B), and other components used if necessary as described later are dissolved or dispersed in a solvent to obtain a specific photosensitive composition.

Specific examples of the solvent include hydrocarbon-based solvents such as benzene, toluene, hexane, and heptane; ether-based solvents such as tetrahydrofuran, 1,4-dioxane, 1,3-dioxolane, and diethyl ether; ketone-based solvents such as acetone, methyl ethyl ketone, methyl isobutyl ketone, and cyclohexanone; glycol-based solvents such as propylene glycol 1-monomethyl ether 2-acetate, diethylene glycol dimethyl ether, diethylene glycol ethyl methyl ether, and ethylene glycol diethyl ether; ester-based solvents such as isobutyl isobutyrate; and halogen-based solvents such as chloroform, methylene chloride, and 1,2-dichloroethane. From the viewpoint of the coatability (film formation stability) of the specific photosensitive composition, the solvent is preferably a glycol-based solvent, more preferably propylene glycol 1-monomethyl ether 2-acetate.

From the viewpoint of applicability (film formation stability) of the specific photosensitive composition, the amount of the solvent is preferably 10 parts by mass or more and 100 parts by mass or less, more preferably 20 parts by mass or more and 80 parts by mass or less, based on 100 parts by mass of the component (A).

{Other Components}

The specific photosensitive composition may contain components other than the above-described component (A) and component (B) (other components) as a solid content (components other than the solvent) as long as the purpose and the effects of the present invention are not impaired. For obtaining a substrate laminate excellent in adhesiveness between substrates while forming a first layer excellent in heat resistance, the total content of the component (A) and the component (B) is preferably 50 mass % or more, more preferably 60 mass % or more, still more preferably 70 mass % or more, even more preferably 80 mass % or more and 100 mass % or less, based on the total solid content of the specific photosensitive composition.

Examples of the other component include a reactive diluent, a crosslinker, a basic compound, a sensitizer, an adhesiveness improver, a thermoplastic resin, a filler, an antioxidant, a radical inhibitor, a polymer dispersant, a mold release agent, a flame retardant, a flame retardant promoter, a surfactant, an antifoaming agent, an emulsifier, a leveling agent, a cissing inhibitor, an ion trapping agent (antimony-bismuth or the like), a thixotropy imparting agent, a tackifier, a storage stability improver, an ozone degradation inhibitor, a light stabilizer, a thickener, a plasticizer, a heat stabilizer, a conductivity imparting agent, an antistatic agent, a radiation blocking agent, a nucleating agent, a phosphorus-based peroxide decomposer, a lubricant, a metal deactivator, a thermal conductivity imparting agent, and a physical property modifier.

(Reactive Diluent)

The specific photosensitive composition may contain a reactive diluent. The reactive diluent is a component which engages in a curing reaction while reducing the viscosity of a specific photosensitive composition. When the specific photosensitive composition contains a reactive diluent, it is possible to reduce shrinkage of the resulting first layer on curing and control the mechanical strength of the first layer.

As the reactive diluent, for example, a compound having two or more cationically polymerizable groups in one molecule is used. Examples of the cationically polymerizable group of the reactive diluent include those exemplified above as the cationically polymerizable group of the component (A). The type of the cationically polymerizable group of the reactive diluent may be identical to or different from the type of the cationically polymerizable group of the component (A). From the viewpoint of enhancing cationic polymerization reactivity, it is preferable that the reactive diluent has an alicyclic epoxy group as a cationically polymerizable group. In a particularly preferred embodiment, the component (A) contains an alicyclic epoxy group as a cationically polymerizable group, and the reactive diluent has two or more alicyclic epoxy groups in one molecule.

Compounds having two or more alicyclic epoxy groups in one molecule include 3′,4′-epoxycyclohexylmethyl 3,4-epoxycyclohexane carboxylate (“CELLOXIDE (registered trademark) 2021P” manufactured by DAICEL CORPORATION), and F-caprolactone-modified-3′,4′-epoxycyclohexylmethyl 3,4-epoxycyclohexane carboxylate (“CELLOXIDE (registered trademark) 2081” manufactured by DAICEL CORPORATION), bis(3,4-epoxycyclohexylmethyl) adipate.

From the viewpoint of improving the curing rate of the specific photosensitive composition and balancing the physical properties of the cured product, the content of the reactive diluent is preferably 2 mass % or more and 50 mass % or less, more preferably 3 mass % or more and 40 mass % or less, based on the total solid content of the specific photosensitive composition.

(Crosslinker)

The specific photosensitive composition may contain a crosslinker from the viewpoint of adjusting workability, reactivity, adhesiveness, and the strength of the first layer. The crosslinker is a compound having two or more photopolymerizable functional groups other than a cationically polymerizable group in one molecule. Examples of the crosslinker include alkoxysilane compounds and (meth)acrylate compounds.

(Basic Compound)

The specific photosensitive composition may contain a basic compound. The basic compound acts as a quencher. That is, by blending an appropriate amount of the basic compound in the specific photosensitive composition, involvement of a non-exposed portion in the photocuring reaction can be prevented. This clarifies the contrast between the exposed portion and the non-exposed portion, resulting in improvement of the resolution.

The blending amount of the basic compound is preferably 0.001 parts by mass or more and 2.0 parts by mass or less, more preferably 0.01 parts by mass or more and 1.0 parts by mass or less, based on 100 parts by mass of the component (A). When the blending amount of the basic compound is 0.001 parts by mass or more, the function as a quencher can be sufficiently exhibited. When the blending amount of the basic compound is 2.0 parts by mass or less, the sensitivity can be improved.

The mass ratio of the basic compound to the photocationic polymerization initiator (basic compound/photocationic polymerization initiator) is, for example, 0.001 or more and 0.2 or less, preferably 0.01 or more and 0.15 or less. When the mass ratio is 0.001 or more, the function as a quencher can be sufficiently exhibited. When the mass ratio is 0.2 or less, crosslinking can be performed adequately.

The basic compound is not particularly limited, and examples thereof include primary, secondary and tertiary aliphatic amine-based compounds, mixed amine-based compounds, aromatic amine-based compounds, heterocyclic amine-based compounds, amide derivatives, and imide derivatives. Among them, aromatic amine-based compounds and heterocyclic amine-based compounds can be suitably used as the basic compound.

Examples of the aromatic amine-based compound and the heterocyclic amine-based compound include aniline, pyrrole, oxazole, thiazole, imidazole, pyrazole, furazan, pyrroline, pyrrolidine, imidazoline, imidazolidine, pyridine, pyridazine, pyrimidine, pyrazine, pyrazoline, pyrazolidine, piperidine, piperazine, morpholine, indole, isoindole, 1H-indazole, indoline, quinoline, cinnoline, quinazoline, quinoxaline, phthalazine, purine, pteridine, carbazole, phenanthridine, acridine, phenazine, 1,10-phenanthroline, adenine, adenosine, guanine, guanosine, uracil, uridine, and derivatives thereof (for example, bis(2-morpholinoethyl)ether). Examples of the heterocyclic amine-based compound also include 2,6-lutidine.

One of the basic compounds may be used alone, or two or more thereof may be used in combination.

(Sensitizer)

The specific photosensitive composition may contain a sensitizer. By using a sensitizer, the exposure sensitivity during patterning is improved. The sensitizer is preferably an anthracene-based compound. Specific examples of the anthracene-based compound include anthracene, 2-ethyl-9,10 dimethoxyanthracene, 9,10-dimethylanthracene, 9,10-dibutoxyanthracene, 9,10-dipropoxyanthracene, 9,10-diethoxyanthracene, 1,4-dimethoxyanthracene, 9-methylanthracene, 2-ethylanthracene, 2-t-butylanthracene, 2,6-di-t-butylanthracene, and 9, 10 diphenyl-2,6-di-t-butylanthracene. Among them, 9,10-dibutoxyanthracene, 9,10-dipropoxyanthracene and, 9,10-diethoxyanthracene are preferable from the viewpoint of compatibility with the specific photosensitive composition.

The content of the sensitizer in the specific photosensitive composition is not particularly limited, and is preferably 0.01 parts by mass or more and 20 parts by mass or less, more preferably 0.1 parts by mass or more and 15 parts by mass or less, based on 100 parts by mass of the component (A), from the viewpoint of curability and the balance of the physical properties of the cured product.

(Adhesiveness Improver)

The specific photosensitive composition may contain an adhesiveness improver. Examples of the adhesiveness improver include various coupling agents, epoxy compounds, oxetane compounds, phenol resins, coumarone-indene resins, rosin ester resins, terpene-phenol resins, α-methylstyrene-vinyltoluene copolymers, polyethylmethylstyrene, and aromatic polyisocyanates.

Examples of the coupling agent include silane coupling agents. The silane coupling agent is not particularly limited as long as it is a compound having at least one reactive functional group and at least one hydrolyzable silicon-containing group in the molecule. The reactive functional group is preferably one or more functional groups selected from the group consisting of an epoxy group, a (meth)acrylic group, an isocyanate group, an isocyanurate group, a vinyl group and a carbamate group from the viewpoint of handleability, and particularly preferably an epoxy group, a methacrylic group or an acrylic group from the viewpoint of curability and adhesiveness. The hydrolyzable silicon-containing group is preferably an alkoxysilyl group from the viewpoint of handleability, and particularly preferably a methoxysilyl group or an ethoxysilyl group from the viewpoint of reactivity.

Examples of the preferred silane coupling agent include alkoxysilane-based compounds having an epoxy group, such as 3-glycidoxypropyltrimethoxysilane, 3-glycidoxypropyltriethoxysilane, 2-(3,4-epoxycyclohexyl)ethyltrimethoxysilane, and 2-(3,4-epoxycyclohexyl)ethyltriethoxysilane; alkoxysilane-based compounds having a (meth)acrylic group, such as 3-methacryloxypropyltrimethoxysilane, 3-methacryloxypropyltriethoxysilane, 3-acryloxypropyltrimethoxysilane, 3-acryloxypropyltriethoxysilane, methacryloxymethyltrimethoxysilane, methacryloxymethyltriethoxysilane, acryloxymethyltrimethoxysilane, andacryloxymethyltriethoxysilane; tris[3-(trimethoxysilylpropyl)]isocyanurate; and γ-isocyanate propyltrimethoxysilane. One of these silane coupling agents may be used alone, or two or more thereof may be used in combination.

The addition amount of the silane coupling agent can be appropriately set, and is preferably 0.1 parts by mass or more and 20 parts by mass or less, more preferably 0.3 parts by mass or more and 10 parts by mass or less, still more preferably 0.5 parts by mass or more and 5 parts by mass or less, based on 100 parts by mass of the compound having a cationically polymerizable group.

(Thermoplastic Resin)

The specific photosensitive composition may contain a thermoplastic resin. Examples of the thermoplastic resin include acryl-based resins, polycarbonate-based resins, cycloolefin-based resins, olefin-maleimide-based resins, polyester-based resins, polyethersulfone resins, polyarylate resins, polyvinyl acetal resins, polyethylene resins, polypropylene resins, polystyrene resins, polyamide resins, silicone resins, fluororesins, and rubber-like resins. The thermoplastic resin may have a crosslinkable group such as an epoxy group, an amino group, a radically polymerizable unsaturated group, a carboxy group, an isocyanate group, a hydroxy group or an alkoxysilyl group.

(Filler)

The specific photosensitive composition may contain a filler. The filler is not particularly limited, and examples of the filler that can be used include inorganic fillers such as silica-based fillers (quartz, fumed silica, precipitated silica, anhydrous silicic acid, fused silica, crystalline silica, ultrafine amorphous silica and the like), silicon nitride, silver powder, alumina, aluminum hydroxide, titanium oxide, glass fiber, carbon fiber, mica, carbon black, graphite, diatomaceous earth, white clay, clay, talc, calcium carbonate, magnesium carbonate, barium sulfate and inorganic balloons, and organic fillers such as epoxy-based fillers.

(Antioxidant)

The specific photosensitive composition may contain an antioxidant. Examples of the antioxidant include common antioxidants such hindered phenol-based antioxidants, and citric acid, phosphoric acid, and sulfur-based antioxidants. As the hindered phenol antioxidant, various antioxidants can be used, such as IRGANOX (registered trademark) 1010 available from BASF SE. Examples of the sulfur-based antioxidant include mercaptan-based compounds, salts of mercaptan-based compounds, sulfide-based compounds (sulfide carboxylic acid ester-based compounds and the like), polysulfide-based compounds, dithiocarboxylic acid salt-based compounds, thiourea-based compounds, thiophosphate-based compounds, sulfonium-based compounds, thioaldehyde-based compounds, thioketone-based compounds, mercaptal-based compounds, mercaptol-based compounds, monothioacid-based compounds, polythioacid-based compounds, thioamide-based compounds, and sulfoxide-based compounds. One of these antioxidants may be used alone, or two or more thereof may be used in combination.

(Radical Inhibitor)

The specific photosensitive composition may contain a radical inhibitor. Examples of the radical inhibitor include phenolic radical inhibitors such as 2,6-di-t-butyl-3-methylphenol (BHT), 2,2′-methylene-bis(4-methyl-6-t-butylphenol) and tetrakis(methylene-3(3,5-di-t-butyl-4-hydroxyphenyl)propionate)methane; and amine-based radical inhibitors such as phenyl-β-naphthylamine, α-naphthylamine, N,N′-secondary butyl-p-phenylenediamine, phenothiazine and N,N′-diphenyl-p-phenylenediamine. One of these radical inhibitors may be used alone, or two or more thereof may be used in combination.

### Preferred Aspect of Method for Manufacturing Substrate Laminate According to First Embodiment

For further suppressing ingress of foreign matter into the substrate laminate while enhancing storage stability at a high temperature and a high humidity and enhancing adhesiveness between substrates, the method for manufacturing a substrate laminate according to the first embodiment satisfies preferably the following condition 1, more preferably the following condition 2, still more preferably the following condition 3.

Condition 1: The reaction ratio of the curable compound in the first layer before step Se is 95% or more, and the content of the alkali component in the first layer before step Se is 1,000 ppm or less.

Condition 2: Condition 1 is satisfied, and the softening point of the first layer before step Se is 100° C. or higher.

Condition 3: Condition 2 is satisfied, and the elastic modulus of the first layer before step Se is 1,500 N/mm² or more as measured by a nanoindentation test method at 100° C.

### Second Embodiment: Substrate Laminate

Next, a substrate laminate according to a second embodiment of the present invention will be described. The substrate laminate according to the second embodiment includes a first substrate, a second substrate, and a cured product layer that bonds the first substrate and the second substrate. The cured product layer includes a first layer including a cured product of a photosensitive composition and a second layer including a cured product of an adhesive in this order from the first substrate side. The first layer is patterned. The photosensitive composition is not particularly limited. It is preferable that the photosensitive composition contains a curable compound having a cationically polymerizable group and a photocationic polymerization initiator, and has alkali solubility.

The substrate laminate according to the second embodiment is obtained by, for example, the manufacturing method according to the first embodiment described above. Thus, in the description of the substrate laminate according to the second embodiment, descriptions of contents overlapping with those of the first embodiment are omitted. The substrate laminate according to the second embodiment is obtained by, for example, the manufacturing method according to the first embodiment described above, and is therefore excellent in adhesiveness between substrates and resistant to ingress of foreign matter.

### Preferred Aspect of Substrate Laminate According to Second Embodiment

For obtaining a substrate laminate that is further excellent in adhesiveness between substrates, reliability evaluated in a thermal shock test, and storage stability at a high temperature and a high humidity and resistant to ingress of foreign matter, the substrate laminate according to the second embodiment satisfies preferably the following condition 1, more preferably the following condition 2, still more preferably the following condition 3, even more preferably the following condition 4, particularly preferably the following condition 5.

Condition 1: The cured product layer further includes a covering layer covering at least a part of the wall surface of the first layer, the covering layer and the second layer are integrated, and the wall surface of the second layer is a curved surface.

Condition 2: Condition 1 is satisfied, and the photosensitive composition as a material for the first layer contains a curable compound having one or more cationically polymerizable groups selected from the group consisting of a glycidyl group and an alicyclic epoxy group.

Condition 3: Condition 2 is satisfied, and the first substrate is a glass substrate.

Condition 4: Condition 3 is satisfied, and the adhesive as a material for the second layer is an epoxy-based adhesive.

Condition 5: Condition 4 is satisfied, and the photosensitive composition as a material for the first layer contains a polysiloxane compound having one or more cationically polymerizable groups selected from the group consisting of a glycidyl group and an alicyclic epoxy group.

### Die Share Strength of Substrate Laminate According to Second Embodiment

The die shear strength of the substrate laminate according to the second embodiment is preferably 10 kgf or more, more preferably 15 kgf or more. The upper limit of the die shear strength of the substrate laminate according to the second embodiment is not particularly limited, and is, for example, 100 kgf or less. The die shear strength can be measured by a method described in examples described later or a similar method.

### Uses of Substrate Laminate According to Second Embodiment

The substrate laminate according to the second embodiment is used as, for example, a member that forms micro electromechanical systems (MEMS). Preferably, the substrate laminate according to the second embodiment is used as a member that forms a sensor such as an image sensor, an acceleration sensor, or a pressure sensor.

When the substrate laminate according to the second embodiment is applied to an image sensor, the image sensor including the substrate laminate according to the second embodiment is excellent in adhesiveness between the substrates, and unlikely to undergo defects (generation of cracks and the like) caused by ingress of foreign matter. In an image sensor including the substrate laminate according to the second embodiment, for example, one of the first substrate and the second substrate is a transparent substrate, and the other is a semiconductor element substrate (image sensor substrate).

Other aspects of the substrate laminate according to the second embodiment are as described above in the sections: [Configuration of substrate laminate obtained by manufacturing method according to first embodiment], [Elements of substrate laminate obtained by manufacturing method according to first embodiment] and [Photosensitive composition].

### EXAMPLES

Hereinafter, the present invention will be described in more detail by way of examples, but the present invention is not limited to these examples.

<Synthesis of Curable Compound (Polysiloxane Compound)>

Hereinafter, methods for synthesis of curable compounds P1 and P2 will be described. The weight average molecular weights of curable compounds P1 and P2 were calculated in terms of standard polystyrene from a chromatogram obtained by measuring the weight average molecular weight at a flow rate of 1.0 mL/min using “HLC-8420 GPC” (Column: Shodex GPC KD-806 M (2 columns) and TSKgel SuperAWM-H (2 columns)) manufactured by Tosoh Corporation, and N,N-dimethylformamide as a solvent.

[Synthesis of Curable Compound P1]

143 μL of a xylene solution of a platinum vinyl siloxane complex (“Pt-VTSC-3X” manufactured by Umicore Precious Metals Japan Co., Ltd., solution with a platinum content of 3 wt %) was added to a mixture of 40 g of diallyl isocyanurate, 29 g of diallyl monomethyl isocyanurate and 264 g of 1,4-dioxane to obtain a solution S1. Meanwhile, 88 g of 1,3,5,7-tetrahydrogen-1,3,5,7-tetramethylcyclotetrasiloxane was dissolved in 176 g of toluene to obtain a solution S2.

In a nitrogen atmosphere containing 3 vol % of oxygen, the solution S1 was added dropwise to the solution S2 over 3 hours with the solution S2 heated at a temperature of 105° C. After completion of the dropwise addition, the mixture was stirred for 30 minutes while being maintained at a temperature of 105° C., thereby obtaining a solution S3. The reaction ratio of the alkenyl group of the compound contained in the obtained solution S3 was measured by ¹H-NMR, and the result showed that the reaction ratio was 95% or more.

Meanwhile, 62 g of 1-vinyl-3,4-epoxycyclohexane was dissolved in 62 g of toluene to obtain a solution S4.

In a nitrogen atmosphere containing 3 vol % of oxygen, the solution S4 was added dropwise to the solution S3 over 1 hour with the solution S3 heated at a temperature of 105° C. After completion of the dropwise addition, the mixture was stirred for 30 minutes while being maintained at a temperature of 105° C., thereby obtaining a solution S5. The reaction ratio of the alkenyl group of the compound contained in the obtained solution S5 was measured by ¹H-NMR, and the result showed that the reaction ratio was 95% or more.

Subsequently, the solution S5 was cooled, and the solvent (toluene, xylene and 1,4-dioxane) was then distilled off from the solution S5 under reduced pressure to obtain a solid. Propylene glycol 1-monomethyl ether 2-acetate (hereinafter, referred to as “PGMEA”) was added to the obtained solid to obtain a solution SP1 containing a curable compound P1 (concentration of the curable compound P1: 70 mass %). The curable compound P1 was a polysiloxane compound having a plurality of cationically polymerizable groups (specifically, alicyclic epoxy groups) and a plurality of alkali-soluble groups (specifically, X2 groups) in one molecule, and a cyclic polysiloxane structure in the main chain (a polymer having a weight average molecular weight of 30,000).

[Synthesis of Curable Compound P2]

Except that 62 g of allyl glycidyl ether was used instead of 62 g of 1-vinyl-3,4-epoxycyclohexane, the same procedure as in [Synthesis of curable compound P1] above was carried out to obtain a solution SP2 containing a curable compound P2 (concentration of the curable compound P2: 70 mass %). The curable compound P2 was a polysiloxane compound having a plurality of cationically polymerizable groups (specifically, glycidyl groups) and a plurality of alkali-soluble groups (specifically, X2 groups) in one molecule, and a cyclic polysiloxane structure in the main chain (a polymer having a weight average molecular weight of 28,000).

<Preparation of Other Materials>

As materials for photosensitive compositions, the following materials were prepared in addition to the solution SP1, the solution SP2 and PGMEA.
Novolac-based resin having phenolic hydroxyl group (“Resitop (registered trademark) PS7802” manufactured by GUN EI Chemical Industry Co., Ltd., hereinafter referred to as “PS7802”).
3′,4′-epoxycyclohexylmethyl 3,4-epoxycyclohexanecarboxylate (“CELLOXIDE (registered trademark) 2021P” manufactured by DAICEL CORPORATION, hereinafter referred to as “2021P”).
Sulfonium salt-based photocationic polymerization initiator (“CPI 210S” manufactured by San-Apro Ltd, hereinafter referred to as “CPI-210S”).
Acid-modified epoxy acrylate (“KAYARAD (registered trademark) 1291H” manufactured by Nippon Kayaku Co., Ltd., hereinafter referred to as “1291 H”).
Trimethylolpropane triacrylate (“A-TMPT” manufactured by Shin-Nakamura Chemical Co., Ltd., a radical polymerizable compound having three acryloyl groups in one molecule, hereinafter referred to as “A-TMPT”).
Benzophenone-based compound as photoradical polymerization initiator (“Omnirad (registered trademark) 651” manufactured by IGM Resins, hereinafter referred to as “651”).

<Preparation of Photosensitive Composition>

The materials shown in Table 1 were blended in the blending amounts shown in Table 1, thereby obtaining photosensitive compositions PS1 to PS4 used in examples and comparative examples. The curable compounds P1 and P2 were blended in the form of the solution SP1 and the solution SP2, respectively. In Table 1, the blending amount of PGMEA in each of the photosensitive compositions PS1 and PS2 also includes the amount of PGMEA in the solution SP1 or the solution SP2. In Table 1, “−” means that the relevant material was not blended.

TABLE 1

| Photosensitive composition | | PS1 | PS2 | PS3 | PS4 |
|---|---|---|---|---|---|
| Blending amount of | Curable compound P1 | 100 | — | — | — |
| each material | Curable compound P2 | — | 100 | — | — |
| (unit: parts by mass) | PS7802 | — | — | 50 | — |
| | 2021P | 15 | 15 | 50 | — |
| | CPI-210S | 1 | 1 | 1 | — |
| | 1291H | — | — | — | 50 |
| | A-TMPT | — | — | — | 50 |
| | 651 | — | — | — | 1 |
| | PGMEA | 50 | 50 | 50 | 50 |

<Production of Substrate Laminate>

Hereinafter, a method for producing a substrate laminate (specifically, a hollow structure having a sealed hollow portion) of each of Examples 1 to 4 and Comparative Examples 1 to 5 will be described.

### Example 1

(Production of Sample 1)

A photosensitive composition PS1 was applied onto a glass substrate as a first substrate by a spin coater to obtain a first laminated product in which a coating film (thickness: 50 μm) formed of the photosensitive composition PS1 is formed on a glass substrate. Subsequently, the first laminated product was heated for 10 minutes on a hot plate heated to a temperature of 120° C. Subsequently, through a photomask (longitudinal direction: line/space=50 μm/50 μm, lateral direction: line/space=100 μm/100 μm) in which a line pattern is formed in a grid shape, the coating film of the heated first laminated product was irradiated with light under the condition of an integrated exposure amount of 3,000 mJ/cm² using a manual exposure machine (“MA-1300” manufactured by Japan Science Engineering Co., Ltd., lamp: high-pressure mercury lamp). In this way, the coating film was exposed (specifically, soft contact exposure).

The exposed first laminated product was allowed to stand in an atmosphere at a temperature of 25° C. for 1 minute, and then immersed in a TMAH aqueous solution (concentration of TMAH: 2.38 mass %) as an alkaline developer for 60 seconds. Subsequently, the first laminated product immersed in the alkaline developer was washed with water for 30 seconds, and moisture on the surface was removed with compressed air.

Subsequently, on a hot plate heated to a temperature of 230° C., the first laminated product free of moisture was heated for 30 minutes to cure the patterned coating film (exposed portion), thereby obtaining a sample 1 having a first layer patterned on a glass substrate (a layer in which a coating film patterned into a grid shape is cured).

(Production of Sample 2)

The sample 1 was cut with a dicing apparatus to obtain a singulated sample 2 with a size of 12 mm×12 mm. The sample 2 is a sample obtained by singulating the sample 1.

(Production of Substrate Laminate)

The sample 2 and a silicon wafer (size: 12 mm×12 mm) as a second substrate were laminated with an epoxy-based adhesive interposed therebetween, thereby obtaining a second laminated product. The lamination was performed so as to interpose the epoxy-based adhesive between the first layer and the silicon wafer. The epoxy adhesive used was a thermosetting adhesive containing bisphenol A diglycidyl ether as a main agent, and an imidazole-based curing agent as a curing agent, where the mass ratio of the main agent to the curing agent (main agent/curing agent) is 100/3.

Subsequently, the second laminated product was heated in an oven at a temperature of 200° C. for 2 hours to obtain a substrate laminate of Example 1. The substrate laminate of Example 1 had a four-layer structure in which a glass substrate, a patterned first layer (a layer including a cured product of the photosensitive composition PS1), a second layer formed of a cured product of an adhesive, and a silicon wafer are laminated in this order.

The following 1) to 5) were confirmed from a scanning electron microscope image of a cross-section of the substrate laminate of Example 1.
1) At least a part of the wall surface of the first layer is covered with a covering layer (a layer integrated with the second layer).
2) The wall surface of the second layer is a curved surface.
3) The shortest distance D on the wall surface of the second layer (arithmetic average value from randomly selected 10 measurement points) is 5 μm.
4) The height of the first layer (arithmetic average value from randomly selected 10 measurement points) is 50 μm.
5) The height of the second layer (arithmetic average value from randomly selected 10 measurement points) is 10 μm.

### Example 2

A substrate laminate of Example 2 was produced in the same manner as in Example 1 except that the photosensitive composition PS2 was used instead of the photosensitive composition PS1. For the substrate laminate of Example 2, it was confirmed from a scanning electron microscope image of a cross-section that at least a part of the wall surface of the first layer was covered with a covering layer (a layer integrated with the second layer), and the wall surface of the second layer was a curved surface.

### Example 3

A substrate laminate of Example 3 was produced in the same manner as in Example 1 except that the photosensitive composition PS3 was used instead of the photosensitive composition PS1. For the substrate laminate of Example 3, it was confirmed from a scanning electron microscope image of a cross-section that at least a part of the wall surface of the first layer was covered with a covering layer (a layer integrated with the second layer), and the wall surface of the second layer was a curved surface.

### Example 4

A substrate laminate of Example 4 was produced in the same manner as in Example 1 except that an ultraviolet curable acryl-based adhesive (“U-2052Z” manufactured by Kemitec Co., Ltd.) was used instead of the epoxy adhesive, and the second laminated product was not heated, but irradiated with an ultraviolet ray from the glass substrate side of the second laminated product to cure the adhesive. For the substrate laminate of Example 4, it was confirmed from a scanning electron microscope image of a cross-section that at least a part of the wall surface of the first layer was covered with a covering layer (a layer integrated with the second layer), and the wall surface of the second layer was a curved surface.

### Comparative Example 1

(Production of Sample 1)

A photosensitive composition PS1 was applied onto a glass substrate as a first substrate by a spin coater to obtain a first laminated product in which a coating film (thickness: 50 μm) formed of the photosensitive composition PS1 is formed on a glass substrate. Subsequently, the first laminated product was heated for 10 minutes on a hot plate heated to a temperature of 120° C. Subsequently, through a photomask (longitudinal direction: line/space=50 μm/50 μm, lateral direction: line/space=100 μm/100 μm) in which a line pattern is formed in a grid shape, the coating film of the heated first laminated product was irradiated with light under the condition of an integrated exposure amount of 3,000 mJ/cm² using a manual exposure machine (“MA-1300” manufactured by Japan Science Engineering Co., Ltd., lamp: high-pressure mercury lamp). In this way, the coating film was exposed (specifically, soft contact exposure).

The exposed first laminated product was allowed to stand in an atmosphere at a temperature of 25° C. for 1 minute, and then immersed in a TMAH aqueous solution (concentration of TMAH: 2.38 mass %) as an alkaline developer for 60 seconds. Subsequently, the first laminated product immersed in the alkaline developer was washed with water for 30 seconds, and moisture on the surface was removed with compressed air to obtain a sample 1 having a patterned semi-cured layer (a layer in which a coating film patterned in a lattice shape is semi-cured state) on a glass substrate.

(Production of Sample 2)

Sample 1 was cut with a dicing apparatus to obtain a singulated sample 2 with a size of 12 mm×12 mm. The sample 2 is a sample obtained by singulating sample 1.

(Production of Substrate Laminate)

A silicon wafer (size: 12 mm×12 mm) as a second substrate was placed on a hot plate heated to a temperature of 150° C. Sample 2 was laminated on the silicon wafer to obtain a second laminated product. The lamination was performed so as to place the semi-cured layer of sample 2 on the silicon wafer side. Subsequently, a 1 kg weight was placed for 10 minutes on the second laminated product placed on the hot plate to pressure-bond the silicon wafer and the glass substrate. Subsequently, the pressure-bonded second laminated product was heated in an oven at a temperature of 200° C. for 2 hours to obtain a substrate laminate of Comparative Example 1. The substrate laminate of Comparative Example 1 had a three-layer structure in which a glass substrate, a layer including a patterned cured product (a layer including a cured product of the photosensitive composition PS1), and a silicon wafer are laminated in this order.

### Comparative Example 2

A substrate laminate of Comparative Example 2 was produced in the same manner as in Comparative Example 1 except that the photosensitive composition PS2 was used instead of the photosensitive composition PS1.

### Comparative Example 3

A substrate laminate of Comparative Example 3 was produced in the same manner as in Comparative Example 1 except that the photosensitive composition PS3 was used instead of the photosensitive composition PS1.

### Comparative Example 4

A substrate laminate of Comparative Example 4 was produced in the same manner as in Example 1 except that the photosensitive composition PS4 was used instead of the photosensitive composition PS1.

### Comparative Example 5

A substrate laminate of Comparative Example 5 was produced in the same manner as in Comparative Example 1 except that the photosensitive composition PS4 was used instead of the photosensitive composition PS1.

<Method for Measuring and Evaluating Physical Properties>

Next, methods for measuring and evaluating various physical properties will be described. Hereinafter, the “first layer or semi-cured layer” is sometimes referred to as a patterned layer.

[Reaction Ratio]

First, solid ¹³CNMR charts of solids in photosensitive compositions PS1 to PS4 were obtained by following the analysis conditions shown below. The area of a peak originating in the “cationically polymerizable group of the curable compound” in the obtained NMR chart was determined, and the obtained peak area was defined as a “first peak area.” Next, a solid ¹³C-NMR chart of the patterned layer of sample 1 (a patterned layer having a mass equal to that of the sample for which the first peak area was measured) was obtained by following the analysis conditions shown below. The area of a peak originating in the “cationically polymerizable group of the curable compound” in the obtained NMR chart was determined, and the obtained peak area was defined as a “second peak area.” The reaction ratio (unit: %) was calculated from the equation “reaction ratio=(1−second peak area/first peak area)×100.” The reaction ratio thus obtained is a reaction ratio of the curable compound in the patterned layer before the silicon wafer and the glass substrate are bonded to each other.

(Solid ¹³C-NMR Analysis Conditions)
Measuring apparatus: nuclear magnetic resonance analyzer (“VNMRS 600” manufactured by Agilent Technologies, Inc.)
Resonance frequency: 150.85 MHz
Measurement mode: DP/MAS method (direct polarization method)
Rotation speed of measurement sample: 20 kHz
Measurement temperature: 25° C.
Cumulative number: 4096
Relaxation delay: 15.000 sec
FID acquisition time: 0.015 sec
Flip angle: 90°

[Content of Alkali Component]

For each of examples and comparative examples, five samples 2 were prepared, the patterned layers were separated, the separated patterned layers (total amount of five samples 2: 4 mg) were put in a container, and 10 mL of ultrapure water was put in the container. TMAH as an alkali component was eluted by a pressure cooker test (PCT) under the conditions of a temperature of 121° C. and 2 atm (absolute pressure) to obtain an eluate containing an alkali component (TMAH). Next, the amount of the alkali component (TMAH) contained in the eluate was measured by ion chromatography. The “content (unit: ppm) of the alkali component (TMAH) in the patterned layer” was calculated from the “amount of the alkali component (TMAH) contained in the eluate.” The thus-obtained content of the alkali component is a content of the alkali component before the silicon wafer and the glass substrate are bonded to each other.

[Patterning Property]

The pattern shape of the patterned layer of sample 1 was observed with a 3D measurement laser microscope (“LEXT (registered trademark) OLS4000” manufactured by Olympus Corporation) and a stylus type surface profile measuring instrument (“Dektak (registered trademark) 150” manufactured by Veeco Instruments Inc.), and evaluated in accordance with the following criteria.

A: Either a residue or peeling does not occur in the pattern region with a line/space of 50 μm/50 μm.

B: One of a residue and peeling occurs in the pattern region with a line/space of 50 μm/50 μm, but either a residue or peeling does not occur in the pattern region with a line/space of 100 μm/100 μm.

C: Cases that do not comply with either A or B above.

[Die Shear Strength]

A shear force was applied to the substrate laminate (specifically, a shear force was applied to the glass substrate and the silicon wafer) using a die shear tester (“SERIES 4000” manufactured by Nordson DAGE), and a load under which the silicon wafer was peeled from the substrate laminate was measured. The maximum value of the load was defined as a die shear strength. The die shear strength was measured under the conditions of a shear height of 50 μm and a shear speed of 80 μm/sec in accordance with MIL STD 883. A sample having a die shear strength of 10 kgf or more was rated as being “excellent in adhesiveness between substrates.” On the other hand, a sample having a die shear strength of less than 10 kgf was rated as “not excellent in adhesiveness between substrates.”

[Softening Point]

The patterned layer was peeled from sample 1, and the softening point of the peeled patterned layer was measured. Specifically, the storage elastic modulus E′ and the loss elastic modulus E″ were measured under the following measurement conditions in accordance with JIS K 7244-4: 1999 “Plastics-Test Methods for Dynamic Mechanical Properties, Part 4: Tensile Vibration-Non-Resonance Method.” From E′ and E″, tan δ (E″/E′) was determined. A temperature corresponding to the vertex of the peak of tan δ, in a graph with the temperature in the horizontal axis and tan δ in the vertical axis, was defined as a softening point. The softening point thus obtained is a softening point of the patterned layer before the silicon wafer and the glass substrate are bonded to each other.

(Conditions for Measurement of Softening Point)

Measuring apparatus: Dynamic viscoelasticity measuring apparatus (“Rheogel-E4000” manufactured by UBM)

Measurement mode: Tensile/sine wave control mode

Initial load: 300 mN

Measurement temperature range: −50° C. to 200° C.

Temperature elevation rate: 3° C./min

Measurement frequency: 1 Hz

[Elastic Modulus]

The elastic modulus of the patterned layer of sample 2 at a temperature of 100° C. was measured by a nanoindentation test method (ISO 14577, Instrumented Indentation Tests). Specifically, sample 2 was placed on a measurement stand of a measuring apparatus in such a manner that the patterned layer of sample 2 faced upward. Next, a load was gradually applied to the patterned layer from above with an indenter, and the displacement against each load (depth to which the patterned layer was depressed with the indenter) was measured to obtain a load-displacement curve. The Young's modulus was calculated from the obtained load-displacement curve, and the calculated Young's modulus was defined as an elastic modulus. The elastic modulus thus obtained is an elastic modulus of the patterned layer before the silicon wafer and the glass substrate are bonded to each other. Detailed measurement conditions are as follows.

Measuring apparatus: nanoindentation tester (“ENT-NEXUS (registered trademark)” manufactured by ELIONIX INC.)

Temperature of sample 2 during measurement (temperature of measurement environment): 100° C.

Indenter approaching rate: 100 nm/sec

Maximum load: 3 mN

Load application rate: 0.6 mN/sec

Maximum load holding time: 5 seconds

Unloading rate: 0.6 mN/sec

Stiffness calculation: At unloading by 10% from the maximum load

Drift calculation: At unloading by 90% from the maximum load

[Foreign Matter Ingress-Preventive Performance]

For each of examples and comparative examples, five samples 2 were prepared, and whether or not foreign matter (having maximum diameter of 50 μm or more) was adhered to the sample was determined by an optical microscope. When foreign matter (having maximum diameter of 50 μm or more) was not adhered to the patterned layer in any of the five samples 2, the sample was rated A (excellent in foreign matter ingress-preventive performance). On the other hand, when foreign matter (having maximum diameter of 50 μm or more) was adhered to the patterned layer in at least one of the five samples 2, the sample was rated B (not excellent in foreign matter ingress-preventive performance).

[Reliability in Thermal Shock Test]

For each of examples and comparative examples, five substrate laminates were prepared, and each subjected to a thermal shock test using a heat shock testing apparatus (“ES-57L” manufactured by Hitachi Global Life Solutions, Inc.). In the thermal shock test, an operation in which the substrate laminate is held in an atmosphere at −55° C. for 30 minutes and then in an atmosphere at 125° C. for 30 minutes was carried out 1,000 times. Subsequently, the substrate laminate was observed from the glass substrate side with an optical microscope, and when a defect (at least one of cracking and peeling) was not observed in any of the five substrate laminates, the sample was rated A (excellent in reliability). On the other hand, when a defect (at least one of cracking and peeling) was observed in at least one of the five substrate laminates, the sample was rated B (not excellent in reliability).

[Storage Stability at High Temperature and High Humidity]

For each of examples and comparative examples, five substrate laminates were prepared, and each put in a thermo-hygrostat bath (“EC-25MHP” manufactured by Hitachi Global Life Solutions, Inc., temperature: 85° C., relative humidity: 85%), and storage stability at a high temperature and a high humidity was evaluated in accordance with the following criteria. An optical microscope was used for examination of foreign matter.

(Evaluation Criteria for Storage Stability at High Temperature and High Humidity)

A: Foreign matter having a maximum diameter of 1 m or more was not stuck on a hollow portion-side surface of the glass substrate in any of the five substrate laminates after 2,000 hours.

B: Foreign matter having a maximum diameter of 1 μm or more was not stuck on the hollow portion-side surface of the glass substrate in any of the five substrate laminates after 1,000 hours, but foreign matter having a maximum diameter of 1 μm or more was stuck on the hollow portion-side surface of the glass substrate in at least one of the five substrate laminates after 2,000 hours.

C: Foreign matter having a maximum diameter of 1 μm or more was not stuck on the hollow portion-side surface of the glass substrate in any of the five substrate laminates after 200 hours, but foreign matter having a maximum diameter of 1 μm or more was stuck on the hollow portion-side surface of the glass substrate in at least one of the five substrate laminates after 1,000 hours.

D: Foreign matter having a maximum diameter of 1 μm or more was stuck on the hollow portion-side surface of the glass substrate in at least one of the five substrate laminates after 200 hours.

For each of Examples 1 to 4 and Comparative Examples 1 to 5, the type of the photosensitive composition used, the presence or absence of the second layer, the type of the adhesive used for formation of the second layer, the reaction ratio, the content of the alkali component, the patterning property evaluation result, the die shear strength, the softening point, the elastic modulus, the result of evaluating foreign matter ingress-preventive performance, the result of evaluating the reliability in the thermal shock test, and the result evaluating storage stability at a high temperature and a high humidity are shown in Tables 2 and 3.

TABLE 2

| | Example 1 | Example 2 | Example 3 | Example 4 |
|---|---|---|---|---|
| Type of | PS1 | PS2 | PS3 | PS1 |
| photosensitive | | | | |
| composition | | | | |
| Presence or absence | Present | Present | Present | Present |
| of second layer | | | | |
| Type of adhesive | Epoxy- | Epoxy- | Epoxy- | Acrylic |
| | based | based | based | adhesive |
| | adhesive | adhesive | adhesive | |
| Reaction ratio [%] | 99 | 99 | 99 | 99 |
| Content of alkali | 60 | 150 | 200 | 60 |
| component [ppm] | | | | |
| Result of evaluation | A | B | B | A |
| of patterning | | | | |
| property | | | | |
| Die shear | 30 | 22 | 20 | 18 |
| strength [kgf] | | | | |
| Softening | 200 | 150 | 170 | 200 |
| point [° C.] | | | | |
| Elastic modulus | 3,500 | 3,200 | 2,800 | 3,500 |
| [N/mm²] | | | | |
| Result of | A | A | A | A |
| evaluation | | | | |
| of foreign | | | | |
| matter ingress- | | | | |
| preventive | | | | |
| performance | | | | |
| Result of | A | A | A | A |
| evaluation of | | | | |
| reliability in | | | | |
| thermal shock | | | | |
| test | | | | |
| Result of evaluation | A | A | B | B |
| of storage stability | | | | |
| at high | | | | |
| temperature | | | | |
| and high humidity | | | | |

TABLE 3

| | Comparative | Comparative | Comparative | Comparative | Comparative |
|---|---|---|---|---|---|
| | Example 1 | Example 2 | Example 3 | Example 4 | Example 5 |
| Type of photosensitive composition | PS1 | PS2 | PS3 | PS4 | PS4 |
| Presence or absence of second layer | None | None | None | Present | None |
| Type of adhesive | Not used | Not used | Not used | Epoxy-based | Not used |
| | | | | adhesive | |
| Reaction ratio [%] | 30 | 25 | 30 | 99 | 95 |
| Content of alkali component [ppm] | 2,000 | 6,000 | 7,000 | 80 | 3,000 |
| Result of evaluation of patterning property | A | B | B | B | B |
| Die shear strength [kgf] | 25 | 18 | 13 | 9 | 1 |
| Softening point [° C.] | 40 | 30 | 30 | 160 | 120 |
| Elastic modulus [N/mm²] | 50 | 40 | 40 | 1,800 | 1,500 |
| Result of evaluation of foreign matter | B | B | B | A | B |
| ingress-preventive performance | | | | | |
| Result of evaluation of reliability in | B | B | B | B | B |
| thermal shock test | | | | | |
| Result of evaluation of storage stability at | D | D | D | D | D |
| high temperature and high humidity | | | | | |

The photosensitive compositions used in Examples 1 to 4 contained a curable compound having a cationically polymerizable group and a photocationic polymerization initiator, and had alkali solubility. In Examples 1 to 4, the patterned layer (first layer including a patterned cured product) and the silicon wafer (second substrate) were bonded to each other, where the second layer including a cured product of the adhesive was interposed therebetween.

In Examples 1 to 4, the die shear strength was 10 kgf or more as shown in Table 2. Thus, the substrate laminates of Examples 1 to 4 were excellent in adhesiveness between substrates. The substrate laminates of Examples 1 to 4 were rated A for the result of evaluating foreign matter ingress-preventive performance. Thus, the substrate laminates of Examples 1 to 4 were excellent in foreign matter ingress-preventive performance.

The photosensitive compositions used in Comparative Examples 4 and 5 did not contain a photocationic polymerization initiator. In Comparative Examples 1 to 3 and 5, the layer obtained by curing the patterned layer (semi-cured layer) and the silicon wafer (second substrate) were bonded to each other without interposition of the second layer.

In Comparative Examples 4 and 5, the die shear strength was less than 10 kgf as shown in Table 3. Thus, the substrate laminates of Comparative Examples 4 and 5 were not excellent in adhesiveness between substrates. The substrate laminates of Comparative Examples 1 to 3 and 5 were rated B for the result of evaluating foreign matter ingress-preventive performance. Thus, the substrate laminates of Comparative Examples 1 to 3 and 5 were not excellent in foreign matter ingress-preventive performance.

The above results show that the present invention can provide a substrate laminate excellent in adhesiveness between substrates and resistant to ingress of foreign matter.

### DESCRIPTION OF REFERENCE CHARACTERS

10 substrate laminate
11 first substrate
12 second substrate
13 cured product layer
131 first layer
132 second layer
133 covering layer
300 coating film
300a exposed portion
300b non-exposed portion
301 photomask
400 adhesive
Z hollow portion

1. A method for manufacturing a substrate laminate, comprising:
a step Sa of applying a photosensitive composition to one surface of a first substrate to form a coating film on the surface;
a step Sb of irradiating the coating film with an active energy ray through a photomask to form an exposed portion formed of a semi-cured photosensitive composition and a non-exposed portion in the coating film;
a step Sc of removing the non-exposed portion from the first substrate with an alkaline developer to form a patterned coating film on the first substrate;
a step Sd of heating the patterned coating film to further cure the semi-cured photosensitive composition, thereby obtaining a first layer including a patterned cured product; and
a step Se of bonding the first layer and a second substrate to each other with an adhesive interposed therebetween, and then curing the adhesive to obtain a second layer that bonds the first layer and the second substrate, wherein
the photosensitive composition contains a curable compound having a cationically polymerizable group and a photocationic polymerization initiator, and has alkali solubility, and
a reaction ratio of the curable compound in the first layer before the step Se is 90% or more.

2. The method for manufacturing a substrate laminate according to claim 1, further comprising a step Sf1 of dicing a laminated product of the first substrate and the first layer to obtain a singulated laminated product after the step Sd and before the step Se, wherein
in the step Se, the first layer of the singulated laminated product and the second substrate are bonded to each other with the adhesive interposed therebetween.

3. The method for manufacturing a substrate laminate according to claim 1, further comprising a step Sf2 of dicing a laminated product, in which the first substrate, the first layer, the second layer, and the second substrate are laminated in this order, to obtain a singulated laminated product after the step Se.

4. The method for manufacturing a substrate laminate according to claim 1, wherein
the alkaline developer contains an alkali component, and
a content of the alkali component in the first layer before the step Se is 1,000 ppm or less.

5. The method for manufacturing a substrate laminate according to claim 1, wherein a softening point of the first layer before the step Se is 100° C. or higher.

6. The method for manufacturing a substrate laminate according to claim 1, wherein an elastic modulus of the first layer before the step Se is 1,500 N/mm² or more as measured by a nanoindentation test method at 100° C.

7. A substrate laminate comprising a first substrate, a second substrate, and a cured product layer that bonds the first substrate and the second substrate, wherein
the cured product layer includes a first layer formed of a cured product of a photosensitive composition and a second layer formed of a cured product of an adhesive, in this order from the first substrate side, and
the first layer is patterned.

8. The substrate laminate according to claim 7, wherein a wall surface of the second layer is a curved surface.

9. The substrate laminate according to claim 7, wherein
the cured product layer further includes a covering layer covering at least a part of a wall surface of the first layer, and
the covering layer and the second layer are integrated.

10. The substrate laminate according to claim 7, wherein one of the first substrate and the second substrate is a transparent substrate.

11. The substrate laminate according to claim 10, wherein one of the first substrate and the second substrate is a transparent substrate, and the other is a semiconductor element substrate.

12. The substrate laminate according to claim 7, wherein the photosensitive composition contains a curable compound having a cationically polymerizable group and a photocationic polymerization initiator, and has alkali solubility.

13. The substrate laminate according to claim 12, wherein the cationically polymerizable group is one or more selected from the group consisting of a glycidyl group and an alicyclic epoxy group.

14. The substrate laminate according to claim 13, wherein the first substrate is a glass substrate.

15. The substrate laminate according to claim 13, wherein the adhesive is an epoxy-based adhesive.

16. The substrate laminate according to claim 12, wherein the curable compound is a polysiloxane compound.

17. The substrate laminate according to claim 16, wherein the polysiloxane compound further contains one or more alkali-soluble groups selected from the group consisting of a monovalent organic group of the following chemical formula X1, a divalent organic group of the following chemical formula X2, a phenolic hydroxyl group, and a carboxy group.

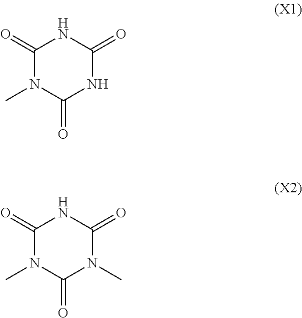

18. The substrate laminate according to claim 7, wherein a height of the first layer is 30 μm or more.

19. The substrate laminate according to claim 7, formed as a hollow structure having a hollow portion between the first substrate and the second substrate.

20. An image sensor comprising the substrate laminate according to claim 7.
